(19) United States
(12) Patent Application Publication
(10) Pub. No.: US 2012/0263946 A1
(43) Pub. Date: Oct. 18, 2012

(54) SEMICONDUCTOR DEVICE, METHOD FOR MANUFACTURING SEMICONDUCTOR DEVICE, AND SEMICONDUCTOR WAFER PROVIDED WITH ADHESIVE LAYER

(76) Inventors: Kazuyuki Mitsukura, Tsukuba-shi (JP); Takashi Kawamori, Tsukuba-shi (JP); Takashi Masuko, Tsukuba-shi (JP); Shigeki Katogi, Tsukuba-shi (JP); Shinjiro Fujii, Hitachi-shi (JP)

(21) Appl. No.: 13/509,362

(22) PCT Filed: Nov. 10, 2010
(86) PCT No.: PCT/JP2010/070014

§ 371 Date: Jun. 22, 2012

(30) Foreign Application Priority Data
Nov. 13, 2009 (JP) 2009-260421
Sep. 3, 2010 (JP) 2010-198108

(51) Int. Cl. B32B 7/12; C09J 7/02; H01L 21/50

(52) U.S. Cl. 428/345; 438/107; 438/113; 428/522; 257/E21.499; 257/E29.002

(57) ABSTRACT

Disclosed is a method for manufacturing a semiconductor device which includes the steps of: forming an adhesive layer by forming an adhesive composition into a film on a surface opposite to the circuit surface of a semiconductor wafer; bringing the adhesive layer to a B-stage by irradiation with light; cutting the semiconductor wafer together with the adhesive layer brought to the B-stage into a plurality of semiconductor chips; and making the semiconductor chip to adhere to a supporting member or another semiconductor chip by performing compression bonding, with the adhesive layer sandwiched therebetween.

### TECHNICAL FIELD

The present invention relates to a semiconductor device and a method for manufacturing such a semiconductor device. Furthermore, the present invention also relates to a semiconductor wafer provided with an adhesive layer, and a semiconductor device using it.

### BACKGROUND ART

A stack package type semiconductor device including a plurality of chips stacked in multiple layers is used for a memory or the like. When a semiconductor device is manufactured, a film-shaped adhesive is applied to cause semiconductor elements to adhere to each other or to cause a semiconductor element to adhere to a supporting member for mounting the semiconductor element. In recent years, as the size and height of electronic components have been reduced, it is required to further reduce the film thickness of the film-shaped adhesive for semiconductor. However, if projections and recesses resulting from wiring or the like are present on the semiconductor element or the supporting member for mounting the semiconductor element, especially when a film-shaped adhesive having a thin film thickness reduced to about 10 μm or less is used, voids tend to be produced at the time of adhesion of the adhesive to an adherend, with the result that the reliability is decreased. Since it is difficult to manufacture the film-shaped adhesive having a thickness of 10 μm or less itself, and, in the film having the reduced film thickness, the sticking property or the thermal-compression-bonding property to a wafer is degraded, it is difficult to produce a semiconductor device using it.

In recent years, in addition to the reduction in the size and thickness of a semiconductor element and its enhanced performance, its multifunctionality has been proceeding and the number of semiconductor devices having a plurality of semiconductor elements stacked has been rapidly increasing. As an adhesive layer between the semiconductor elements or between the lower most semiconductor element and a substrate (supporting member), a film-like adhesive (die bonding material) is mainly being applied.

As the reduction in the film thickness of a semiconductor device further progresses, the need for the reduction in the film thickness of the adhesive layer is becoming higher. Furthermore, in order to simplify the process of assembling a semiconductor device using a film-like die bonding material (hereinafter, referred to as a die bonding film), the bonding process to the back surface of the wafer may be simplified by the method of using an adhesive sheet having a dicing sheet bonded to one surface of the die bonding film, that is, a film in which the dicing sheet is formed integrally with the die bonding film (hereinafter, may be referred to as a “dicing-die bonding integral film”). Since, in accordance with this method, the process of bonding the film to the back surface of the wafer can be simplified, it is possible to reduce the risk of the breaking of the semiconductor wafer. Moreover, in order to suppress the breaking of the semiconductor wafer resulting from the peeling-off of a back grind tape in a semiconductor wafer in which its thickness is reduced by a back grind process, the process in which the dicing-die bonding integral film is bonded to the other surface of the semiconductor wafer in a state where the back grind tape is bonded to one surface of the semiconductor wafer, is effective particularly for reducing the risk of the breaking of the semiconductor wafer having the thickness significantly reduced.

The softening temperature of the dicing sheet and the back grind tape is generally 100° C. or less. It is necessary to reduce the warpage of the semiconductor wafer in which its size is increased and its thickness is reduced. Therefore, when an adhesive layer (die bonding material layer) is formed on the back surface of the semiconductor wafer with the back grind tape provided on the circuit surface, the adhesive layer is preferably formed either by heating of 100° C. or less or without heating.

Although it is highly required to reduce the thickness of the adhesive layer (die bonding material layer), it is difficult to obtain a film-shaped die bonding material having a thickness of 20 μm or less by the application of an adhesive composition; even if such a film-shaped die bonding material is obtained, its operability in the manufacturing tends to be decreased.

In order to reduce the thickness of the adhesive layer between the semiconductor elements and the adhesive layer between the lowermost semiconductor element and the substrate and to reduce the cost of the semiconductor, for example, as disclosed in patent documents 1 and 2, a method is being examined of forming an adhesive layer brought to a B-stage by applying a liquid adhesive composition (resin paste) containing a solvent to the back surface of the semiconductor wafer and volatilizing the solvent from the applied resin paste through heating.

### CITATION LIST

### Patent Literature

Patent document 1: Japanese Unexamined Patent Application Publication No. 2007-110099
Patent document 2: Japanese Unexamined Patent Application Publication No. 2010-37456

### SUMMARY OF INVENTION

### Technical Problem

However, when the resin paste containing the solvent is used, there are problems in which it takes a long time to volatilize the solvent to bring the paste to a B-stage or the semiconductor wafer is contaminated by the solvent. Moreover, there have been problems in which heating for drying to volatilize the solvent prevents a pressure sensitive tape from being easily peeled off when the resin paste is applied to a wafer with the pressure sensitive tape that can be peeled off, and causes the warpage of the wafer. When drying is performed at a low temperature, the failure resulting from the heating can be somewhat suppressed, but in that case, the amount of solvent left is increased, and thus voids and/or the peeling-off are caused at the time of thermal curing, with the result that the reliability tends to be decreased. When a low boiling solvent is used to reduce the drying temperature, the viscosity tends to be greatly changed during use. Furthermore, since the volatilization of the solvent on the surface of the adhesive advances at the time of drying, the solvent is left within the layer of the adhesive, with the result that the reliability also tends to be decreased.

When the liquid die bonding material (resin paste) containing the solvent is used, it is necessary to perform heating at a high temperature to volatize the solvent at the time of being brought to a B-stage after the application to the back surface of the semiconductor wafer. When the heating temperature for being brought to a B-stage exceeds 100° C., it is difficult to form the adhesive layer brought to a B-stage with the back grind tapes whose softening temperature is 100° C. or less stacked in layers on the circuit surface of the semiconductor wafer. Moreover, the semiconductor wafer with reduced thickness tends to be more likely to be warped. When a liquid die bonding material containing a solvent having a lower boing point is used in order to reduce the heating temperature for being brought to a B-stage, since the stability of the viscosity of an application solution is degraded, it is difficult to form the adhesive layer having a uniform thickness. Therefore, it tends to be impossible to obtain sufficient adhesion strength.

The present invention has been made in view of the foregoing conditions and a main object of the present invention is to provide a method which can further reduce the thickness of a layer of an adhesive for adhesion of a semiconductor chip to a supporting member or another semiconductor chip while maintaining the high reliability of a semiconductor device. Furthermore, another object of the present invention is to provide an semiconductor wafer with adhesive layer that can be obtained without need for heating at a high temperature, and can achieve sufficient adhesion strength even when the thickness of the adhesive layer is reduced.

### Solution to Problem

The present invention relates to a method for manufacturing a semiconductor device, the method including the steps of forming an adhesive layer by forming an adhesive composition into a film on a surface opposite to a circuit surface of a semiconductor wafer; bringing the adhesive layer to a B-stage by irradiation with light; cutting the semiconductor wafer together with the adhesive layer brought to a B-stage into a plurality of semiconductor chips; and making the semiconductor chip to adhere to a supporting member or another semiconductor chip by performing compression bonding, with the adhesive layer sandwiched therebetween.

In the method according to the present invention, the adhesive composition is formed into a film on the surface (back surface) opposite to the circuit surface of the semiconductor wafer, and thus it is possible to easily reduce the thickness of the adhesive layer. Furthermore, since a step of volatizing the solvent from the adhesive composition by hearing is not needed, even when the layer of the adhesive for adhesion of the semiconductor chip to the supporting member or another semiconductor chip is reduced in thickness, it is possible to maintain high reliability of the semiconductor device.

In the method according to the present invention, the adhesive composition can be formed into the film in a state in which a back grind tape is provided on the circuit surface of the semiconductor wafer.

The viscosity of the adhesive composition at 25° C. before being brought to a B-stage by irradiation with light is preferably 10 to 30000 mPa·s.

The film thickness of the adhesive layer brought to a B-stage by irradiation with light is preferably 30 μm or less.

The shear strength at 260° C. after adhesion of the semiconductor chip to the supporting member or the another semiconductor chip is preferably 0.2 MPa or more.

The back surface of the semiconductor wafer is preferably coated with the adhesive composition by a spin coat method or a spray coat method.

The 5% weight reduction temperature of the adhesive composition that has been brought to a B-stage by irradiation with light and then cured by heating is preferably 260° C. or more.

The adhesive composition preferably includes a photoinitiator. The adhesive composition preferably includes a compound having an imide group. The compound having an imide group can be a thermoplastic resin such as a polyimide resin or a low-molecular weight compound such as a (meth)acrylate having an imide group.

The present invention also relates to a semiconductor device that can be obtained by the manufacturing method according to the present invention described above. The semiconductor device according to the present invention has sufficiently high reliability even when the layer of the adhesive for adhesion of the semiconductor chip to the supporting member or another semiconductor chip is reduced in thickness.

The present invention also relates to an semiconductor wafer with an adhesive layer including: a semiconductor wafer; and an adhesive layer that is formed on a surface opposite to a circuit surface of the semiconductor wafer. The adhesive layer has been brought to a B-stage by exposure, and the maximum melt viscosity of the adhesive layer at a temperature of 20 to 60° C. is 5000 to 10000 Pa·s.

The semiconductor wafer with an adhesive layer according to the present invention described above can be obtained without need of heating at a high temperature. Consequently, it is possible to reduce the warpage of the semiconductor wafer after making a B-stage while maintain high reliability of the semiconductor device. Moreover, in the semiconductor wafer with an adhesive layer according to the present invention described above, even when the thickness of the adhesive layer is reduced to, for example, 20 μm or less, it is possible to achieve sufficient adhesion strength.

The adhesive composition that forms the adhesive layer included in the semiconductor wafer with an adhesive layer according to the present invention can be suitably used for manufacturing a semiconductor device in which a plurality of semiconductor elements are stacked using a significantly thin wafer, by a wafer back surface coating method. With the adhesive composition described above, it is possible to form the adhesive layer on the back surface of the wafer without heating and for a short period of time to significantly reduce thermal stress on the wafer. Consequently, even when a wafer whose diameter is increased and whose thickness is reduced is used, it is possible to significantly reduce the occurrence of a problem such as the warpage.

The lowest melt viscosity of the adhesive layer at a temperature of 80 to 200° C. is preferably 5000 Pa·s or less. Although the lower limit of the lowest melt viscosity is not particularly set, since it is possible to reduce foaming at the time of thermal compression bonding, it is preferably 10 Pa·s or more.

The adhesive layer incorporating semiconductor element obtained by dividing the semiconductor wafer with an adhesive layer into pieces can be compression bonded and fixed to an adherend such as one of the semiconductor elements or the supporting member via the adhesive layer at a lower temperature, and can also be die bonded at a low temperature and a low pressure and for a short period of time. Thermal fluidity that allows embedment in a wiring step on a substrate at a low pressure at the time of the die bonding is also provided. Since the adhesion to the adherend such as the semiconductor element and the supporting member is good, it is possible to help increase the efficiency of the process of assembling the semiconductor device.

In other words, according to the present invention, the adhesive layer can acquire the thermal fluidity that allows good embedment in the wiring step on the surface of the substrate. Therefore, it can be suitable for the process of manufacturing the semiconductor device in which a plurality of semiconductor elements is stacked. Furthermore, since high adhesion strength at a high temperature can be acquired, it is possible to enhance heat resistance and moisture resistance reliability and simplify the process of manufacturing the semiconductor device.

The adhesive layer is preferably a layer that is formed into a film in a state in which a back grind tape is provided on the circuit surface of the semiconductor wafer.

The adhesive layer is formed in a state in which the back grind tape is provided on the circuit surface of the semiconductor wafer, and thus, when the adhesive layer is formed on the back surface of the semiconductor wafer that has undergone the back grind step, it is possible to form the adhesive layer, without heating, on the back surface of the semiconductor wafer to which the back grind tape having a low softening temperature is bonded. Therefore, thermal damage is prevented from being produced in the back grind tape, and the dicing sheet having stickiness is bonded to one surface on the side of the adhesive layer formed on the back surface of the semiconductor wafer, and thereafter a series of processes for removing the back grind tape from the semiconductor wafer can be achieved without heating. In this way, it is possible to suppress both the warpage of the semiconductor wafer having significantly reduced thickness and the cracking of the semiconductor wafer due to tape peeling, with the result that it becomes possible to realize the process of manufacturing the semiconductor device which uses a significantly thin semiconductor wafer and which is subjected to “low stress” or “no damage”

The semiconductor wafer with adhesive layer according to the present invention may further include a dicing sheet. The dicing sheet is provided on a surface of the adhesive layer opposite to the semiconductor wafer. Preferably, the dicing sheet includes a base material film and a pressure sensitive adhesive layer provided on the base material film, and is provided in a direction in which the pressure sensitive adhesive layer is positioned on the side of the adhesive layer.

Since the semiconductor wafer further includes a dicing sheet, and the dicing sheet is provided on the surface of the adhesive layer side, it is possible to obtain the semiconductor wafer that is easy to handle; moreover, the semiconductor wafer with adhesive layer having the dicing sheet can further simplify the process of manufacturing the semiconductor device, by having the pressure sensitive adhesive layer that functions as both the dicing sheet and a die bonding material.

Furthermore, the present invention has an advantage in that operability or productivity when the semiconductor device is manufactured, such as the reduction of chip flying at the time of dicing and pickup property is enhanced. It is also possible to maintain stable properties for the thermal history of assembly of a package.

Preferably, the adhesive layer is formed with an adhesive composition in which the viscosity of the adhesive composition at 25° C. before being brought to a B-stage is 10 to 30000 mPa·s.

Preferably, the adhesive layer is a layer that is formed by bringing an adhesive composition including (A) a compound having a carbon-carbon double bond and (B) a photoinitiator to a B-stage.

Preferably, (A) the compound having a carbon-carbon double bond includes a monofunctional (meth)acrylate compound. Preferably, the monofunctional (meth)acrylate compound includes a compound having an imide group.

Furthermore, the present invention is related to a semiconductor device including one or two or more semiconductor elements and a supporting member. At least one of the one or two or more semiconductor elements is a semiconductor element that is obtained by cutting the semiconductor wafer with an adhesive layer according to the present invention into pieces, and the semiconductor element is made via the adhesive layer to adhere to another semiconductor element or the supporting member.

The semiconductor device of the present invention has its manufacturing process simplified and has excellent reliability. The semiconductor device of the present invention can sufficiently achieve heat resistance and moisture resistance required when the semiconductor element is mounted.

The semiconductor device according to the present invention can simultaneously achieve the stacking of significantly thin incorporated semiconductor elements in layers and the reduction of its size and thickness, has high performance, high function and high reliability (in particular, reflow resistance, heat resistance, moisture resistance and the like) and can be manufactured highly efficiently through a step using ultrasound processing such as wire bonding.

### Advantageous Effects of Invention

According to the present invention, even when the layer of an adhesive for adhesion of a semiconductor chip to a supporting member or another semiconductor chip is decreased in thickness, it is possible to manufacture the semiconductor device having high reliability. According to the present invention, there is provided an semiconductor wafer with adhesive layer which can be obtained without need of heating at a high temperature and which can have sufficient adhesion strength even when the thickness of the adhesive layer is reduced. Consequently, it is possible to suppress, while maintaining the high reliability of the semiconductor device, the warpage of the semiconductor wafer after being brought to a B-stage and to reduce the thickness of the adhesive layer for adhesion of the semiconductor element to the supporting member or another semiconductor element.

### BRIEF DESCRIPTION OF DRAWINGS

FIG. 1 A schematic cross-sectional view showing an embodiment of a semiconductor wafer;

FIG. 2 A schematic cross-sectional view showing an embodiment of an semiconductor wafer with adhesive layer;

FIG. 3 A schematic cross-sectional view showing an embodiment of an semiconductor wafer with adhesive layer in which the adhesive layer is formed into a film in a state in which a back grind tape is provided on the circuit surface of the semiconductor wafer;

FIG. 4 A schematic cross-sectional view showing an embodiment of a semiconductor device;

FIG. 5 A schematic cross-sectional view showing another embodiment of the semiconductor device;

FIG. 6 A schematic view showing an embodiment of the method for manufacturing the semiconductor device;

FIG. 7 A schematic view showing an embodiment of the method for manufacturing the semiconductor device;

FIG. 8 A schematic view showing an embodiment of the method for manufacturing the semiconductor device;

FIG. 9 A schematic view showing an embodiment of the method for manufacturing the semiconductor device;

FIG. 10 A schematic view showing an embodiment of the method for manufacturing the semiconductor device;

FIG. 11 A schematic view showing an embodiment of the method for manufacturing the semiconductor device;

FIG. 12 A schematic view showing an embodiment of the method for manufacturing the semiconductor device;

FIG. 13 A schematic view showing an embodiment of the method for manufacturing the semiconductor device;

FIG. 14 A schematic view showing an embodiment of the method for manufacturing the semiconductor device;

FIG. 15 A schematic view showing an embodiment of the method for manufacturing the semiconductor device;

FIG. 16 A schematic view showing an embodiment of the method for manufacturing the semiconductor device; and

FIG. 17 A schematic view showing an embodiment of the method for manufacturing the semiconductor device.

### DESCRIPTION OF EMBODIMENTS

Embodiments of the present invention will be described below in detail with reference to accompanying drawings as necessary. However, the present invention is not limited to the embodiments described below. In the drawings, the same or corresponding elements are identified with the same symbols. The repeated descriptions will be omitted as appropriate. Unless otherwise specified, the positional relationship such as the top, the bottom, the left and the right is based on the positional relationship shown in the drawings. The dimensional ratio is not limited to the ratio shown in the figures.

In the present specification, “B-stage” means an intermediate stage of a curing reaction, that is, a stage in which a melt viscosity is increased. A resin composition brought to a B-stage is softened by heating. Specifically, the maximum value of the melt viscosity (the maximum melt viscosity) of an adhesive layer brought to a B-stage at temperatures of 20° C. to 60° C. is preferably 5000 to 100000 Pa·s; the maximum value is more preferably 10000 to 100000 Pa·s from the viewpoint of good handling characteristics and pickup property.

An semiconductor wafer with adhesive layer according to the present invention includes a semiconductor wafer and the adhesive layer brought to a B-stage by exposure. The adhesive layer is formed on the surface on the side opposite to the circuit surface of the semiconductor wafer.

The maximum melt viscosity of the adhesive layer brought to a B-stage at temperatures of 20° C. to 60° C. is preferably 5000 to 100000 Pa·s. Thus, it is possible to obtain a good self-supporting property of the adhesive layer. The maximum melt viscosity is more preferably 10000 Pa·s or more. Thus, the stickiness of the surface of adhesive layer is reduced, and the preservation stability of the semiconductor wafer with adhesive layer is enhanced. The maximum melt viscosity is further preferably 30000 Pa·s or more. Thus, the hardness of the adhesive layer is increased, and thus the adhesion to a dicing tape by applying pressure is easily performed. The maximum melt viscosity is further more preferably 50000 Pa·s or more. In this way, the tack strength on the surface of the adhesive layer is sufficiently reduced, and thus it is possible to ensure good peeling property from the dicing tape after a dicing process. When the peeling property is good, it is possible to favorably ensure the pickup property of the semiconductor wafer with the adhesive layer after the dicing process.

When the maximum melt viscosity is below 5000 Pa·s, the tack force on the surface of the adhesive layer brought to the B-stage tends to be excessively increased. Therefore, when semiconductor chips obtained by dividing the semiconductor wafer with the adhesive layer through dicing into individual pieces are picked up together with the adhesive layer, the semiconductor chips tend to be easily broken, since the peeling force of the adhesive layer from the dicing sheet is excessively high. The maximum melt viscosity is preferably 100000 Pa·s or less from the viewpoint of suppressing the warpage of the semiconductor wafer.

The minimum value of the melt viscosity (viscosity) (the lowest melt viscosity) at temperatures of 20° C. to 300° C. of the adhesive composition (adhesive layer) brought to the B-stage by irradiation with light is preferably 30000 Pa·s or less.

The lowest melt viscosity is more preferably 20000 Pa·s or less, further preferably 18000 Pa·s or less and particularly preferably 15000 Pa·s or less. When the adhesive composition has the lowest melt viscosity within the range described above, it is possible to ensure more excellent low temperature thermal compression bonding of the adhesive layer. Furthermore, it is possible to impart good adherence to a substrate or the like having projections and recesses, to the adhesive layer. The lowest melt viscosity is preferably 10 Pa·s or more in terms of handing or the like.

The minimum value of the melt viscosity (the lowest melt viscosity) of the adhesive layer at temperatures of 80° C. to 200° C. is preferably 5000 Pa·s or less. Because of this, thermal fluidity at a temperature of 200° C. or less is enhanced, and thus it is possible to ensure good thermal compression bonding at the time of die bonding. In addition, the lowest melt viscosity is more preferably 3000 Pa·s or less. Therefore, when the semiconductor chip is thermal compression bonded to an adherend such as a substrate in which steps are formed on its surface at a relatively low temperature of 200° C. or less, sufficient embedding of the steps becomes further easy in the adhesive layer. The lowest melt viscosity is further preferably 1000 Pa·s or less. This makes it possible to maintain good fluidity at the time of thermal compression bonding of a thin adhesive layer. Furthermore, it is possible to perform the thermal compression bonding at a lower pressure, and this is especially advantageous when the semiconductor chip is extremely thin. The lower limit of the lowest melt viscosity is preferably 10 Pa·s or more and is more preferably 100 Pa·s or more, from the viewpoint of suppressing foaming at the time of heating. When the lowest melt viscosity exceeds 5000 Pa·s or more, lack of fluidity at the time of thermal compression bonding may prevent sufficient wettability on a supporting substrate or an adherend such as the semiconductor element from being acquired. When wettability lacks, sufficient adhesion cannot be held in the subsequent assembly of the semiconductor device, and thus the reliability of the obtained semiconductor device is more likely to be reduced. Moreover, since a high thermal compression bonding temperature is needed to ensure sufficient fluidity of the adhesive layer, thermal damage to peripheral members such as the warpage of the semiconductor element after the semiconductor element has been made to adhere and fixed tends to be increased.

The maximum melt viscosity and the lowest melt viscosity are values measured by the following method. First, the adhesive composition is applied onto a PET film such that its film thickness is 50 μm, the applied film obtained is exposed, under the air of room temperature, from the side of the surface opposite to the PET film, at 1000 mJ/cm² through the use of a high precision parallel exposure device (“EXM-1172-B-∞” (trade name) manufactured by ORC Manufacturing Co., Ltd.) and the adhesive layer brought to a B-stage is formed. The formed adhesive layer is made to adhere to a Teflon (registered trade mark) sheet, and is pressurized by a roll (at a temperature of 60° C., a linear pressure of 4 kgf/cm, a transfer rate of 0.5 m/minute). After that, the PET film is peeled off, and another adhesive layer brought to the B-stage by exposure is laid on the adhesive layer, and they are stacked while being pressurized. By repeating this, an adhesive sample having a thickness of about 200 μm is obtained. The melt viscosity of the obtained adhesive sample is measured, through the use of a viscoelasticity measurement device (manufactured by Rheometric Scientific F.E. Ltd., the trade name: ARES) and a parallel plate having a diameter of 25 mm as a measurement plate, under the conditions of a temperature rise rate of 10° C./minute, a frequency of 1 Hz and measurement temperatures of 20 to 200° C. or 20 to 300° C. The maximum melt viscosity at temperatures of 20 to 60° C. and the minimum melt viscosity at temperatures of 80 to 200° C. are read from the relationship between the obtained melt viscosity and the temperature.

The viscosity at 25° C. before the adhesive layer is brought to a B-stage, that is, the viscosity of the adhesive composition that is formed into a film on the semiconductor wafer, is preferably 10 to 30000 mPa·s. This makes it possible not only to suppress the generation of cissing or pinholes when the adhesive composition is applied but also to achieve excellent thin film formation. The viscosity described above is more preferably 30 to 20000 mPa·s. Because of this, the uniform control of the coating amount of the adhesive composition is possible when the adhesive composition is applied by a spin coat or the like. The viscosity described above is further preferably 50 to 10000 mPa·s. Because of this, it becomes easier to form a thin adhesive layer by coating with a spin coat or the like. The viscosity described above is further preferably 100 to 5000 mPa·s. Because of this, it becomes further easier to apply the adhesive composition to the semiconductor wafer having a large diameter with a spin coat or the like and thereby form a thin adhesive layer. If the viscosity described above is below 10 mPa·s, when the adhesive composition is applied, cissing or pinholes tends to be more likely to be produced. If the viscosity described above exceeds 30000 mPa·s, it tends to become difficult to reduce the thickness of the obtained adhesive layer and it tends to become difficult to discharge the adhesive composition from a nozzle at the time of coating with a spin coat or the like. The viscosity described above is a value measured 10 minutes after the start of the measurement, through the use of an E-type viscometer (EI-ID-type rotation viscometer, a standard cone) manufactured by Tokyo Keiki Inc., at a measurement temperature of 25° C. and at a sample capacity of 4 cc. The number of revolutions of the viscometer is set as shown in table 1 depending on the expected viscosity of the sample.

TABLE 1

| Viscosity(mPa · s) | Number of revolutions (rpm) |
|---|---|
| 102400 - 10240 | 0.5 |
| 51200 - 5120 | 1.0 |
| 20480 - 2048 | 2.5 |
| 10240 - 1024 | 5.0 |
| 5120 - 512 | 10 |
| 2560 - 256 | 20 |
| 1024 - 102.4 | 50 |
| 512 - 51.2 | 100 |

The adhesive layer described above is preferably a layer that is formed by bringing an adhesive composition containing at least (A) a compound having a carbon-carbon double bond and (B) a photoinitiator, to a B-stage. The adhesive composition described above more preferably contains (C) an epoxy resin. This makes it possible to solidify the coating film after being brought to the B-stage or reduce the tacking, and this contributes to the efficiency of the semiconductor device assembly process such as a dicing step. The semiconductor device having the adhesive layer obtained from the adhesive composition described above can highly satisfy the reliability of the semiconductor device such as reflow resistance.

(A) The compound having a carbon-carbon double bond is not particularly limited as long as the compound has an ethylenically unsaturated group within its molecule. Preferable examples of the ethylenically unsaturated group include a vinyl group, an allyl group, a propargyl group, a butenyl group, an ethynyl group, a phenyl ethynyl group, a maleimide group, a nadiimide group, a (meth)acrylic group and the like. Among them, a (meth)acrylic group, which will be described later and which shows good radiation polymerization when combined with the (B) photoinitiator is preferable. By selecting a compound having a (meth)acrylic group within the molecule, it is possible to highly satisfy low tacking of the adhesive layer after being brought to the B-stage and the thermal compression bonding property at a low temperature after being brought to the B-stage. It is also possible to impart thermal fluidity that can allow embedding into wiring steps on the substrate at a low pressure at the time of die bonding.

The amount of (A) the compound having a carbon-carbon double bond is preferably 10 to 95 weight %, more preferably 20 to 90 weight % and further preferably 40 to 90 weight %, of the total amount of the adhesive composition. When the component (A) is less than 10 weight %, the tack force after being brought to the B-stage tends to be increased; when the component (A) exceeds 95 weight %, the adhesion strength after thermal curing tends to be decreased.

Examples of the compound having a vinyl group include, for example, styrene, divinyl benzene, 4-vinyl toluene, 4-vinyl pyridine, and N-vinyl pyrolidone.

Examples of the compound having a (meth)acrylic group include diethylene glycol diacrylate, triethylene glycol diacrylate, tetraethylene glycol diacrylate, diethylene glycol dimethacrylate, triethylene glycol dimethacrylate, tetraethylene glycol dimethacrylate, a trimethylolpropane diacrylate, trimethylol propane triacrylate, a trimethylol propane dimethacrylate, trimethylol propane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, a pentaerythritol trimethacrylate, pentaerythritol tetramethacrylate, a dipentaerythritol hexaacrylate, dipentaerythritol hexamethacrylate, 2-hydroxyethyl acrylate, 2-hydroxyethyl methacrylate, 1,3-acryloyloxy-2-hydroxyl propane, 1,2-methacryloyloxy-2-hydroxy propane, methylene bis acrylamide, N,N-dimethyl acrylamide, N-methylol acrylamide, triacrylate of tris(β-hydroxyethyl) isocyanurate, a compound such as an ethoxylated bisphenol A-type acrylate expressed by the following general formula (18) and poly-functional (meth)acrylates such as urethane acrylate, urethane methacrylate and urea acrylate.

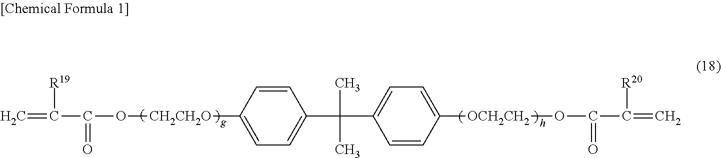

In the formula, R¹⁹ and R²⁰ individually represent a hydrogen atom or a methyl group, and g and h individually represent integers of 1 to 20.

Other examples of the compound having a (meth)acrylic group include a glycidyl group containing (meth)acrylate, a phenol EO-modified (meth)acrylate, a phenol PO-modified (meth)acrylate, a nonylphenol EO-modified (meth)acrylate, a nonylphenol PO-modified (meth)acrylate, a phenolic hydroxyl group containing (meth)acrylate, a hydroxyl group containing (meth)acrylate, an aromatic (meth)acrylate such as a phenylphenol glycidyl ether (meth)acrylate, a phenoxyethyl (meth)acrylate, and a phenoxydiethylene glycol acrylate, an imide group containing (meth)acrylate such as 2-(1,2-cyclohexacarboxylmide) ethylacrylate, a carboxyl group containing (meth)acrylate, an isobornyl containing (meth)acrylate, a dicyclopentadienyl group containing (meth)acrylate, a monofunctional (meth)acrylate such as an isobornyl (meth)acrylate, a glycidyl methacrylate, a glycidyl acrylate, 4-hydroxybutyl acrylate glycidyl ether and 4-hydroxy butyl methacrylate glycidyl ether. A compound that is obtained by making a compound having a functional group reacting with an epoxy resin and a (meth)acrylic group to react with a polyfunctional epoxy resin can also be used. The functional group reacting with an epoxy resin is not particularly limited, but examples thereof include an isocyanate group, a carboxyl group, a phenolic hydroxyl group, a hydroxyl group, acid anhydride group, an amino group, a thiol group, an amide group and the like.

In addition to what has been described above, examples of the monofunctional (meth)acrylate having an epoxy group include a glycidyl ether of bisphenol A-type (or AD-type, S-type or F-type), a glycidyl ether of hydrogenated bisphenol A-type, a glycidyl ether of ethylene oxide adduct bisphenol A-type and/or F-type, a glycidyl ether of propylene oxide adduct bisphenol A-type and/or F-type, a glycidyl ether of phenol novolak resin, a glycidyl ether of cresol novolak resin, a glycidyl ether of bisphenol A novolak resin, a glycidyl ether of naphthalene resin, a glycidyl ether of 3 functional type (or 4 functional type), a glycidyl ether of dicyclopentadiene phenol resin, a glycidyl ester of dimer acid, a glycidyl amine of 3 functional type (or 4 functional type) and a compound using, as the raw material, glycidyl amine of naphthalene resin or the like. From the viewpoint of ensuring the thermal compression bonding property, low stress and adhesiveness, each of the number of epoxy groups and the number of ethylenically unsaturated groups is preferably three or less, in particular, the number of ethylenically unsaturated groups is preferably two or less. As these compounds, compounds represented by, for example, the following general formulas (13), (14), (15), (16) or (17) are preferably used.

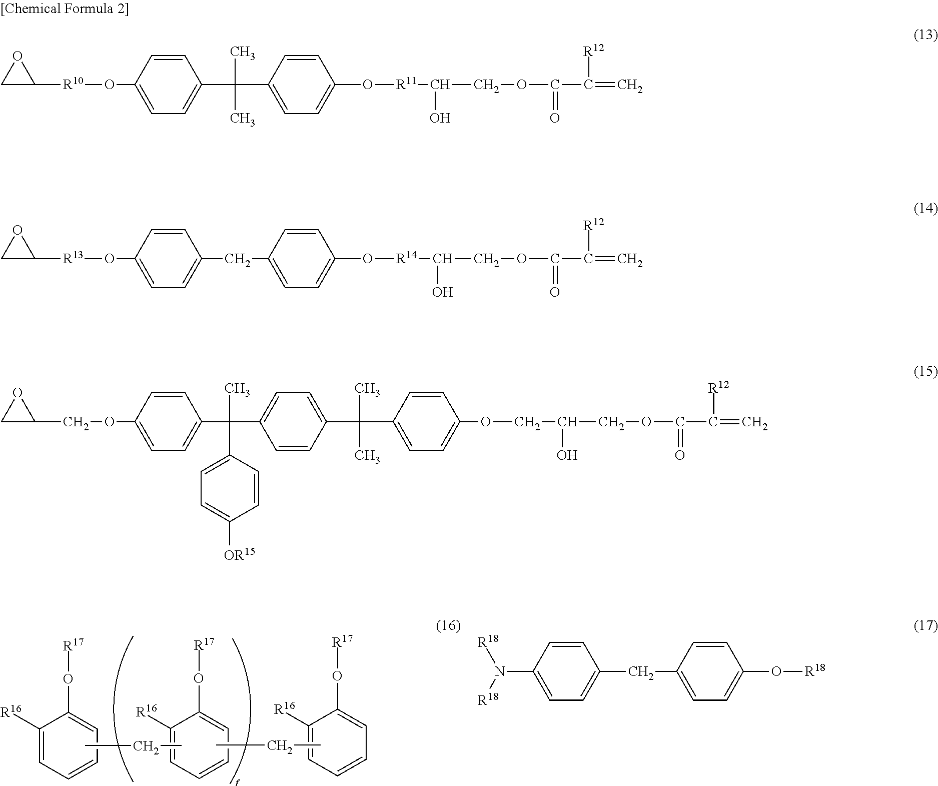

In the formulas, R¹² and R¹⁶ each represent a hydrogen atom or a methyl group, R¹⁰, R¹¹, R¹³ and R¹⁴ each represent a divalent organic group and R¹⁵, R¹⁷ and R¹⁸ each represent an organic group having an epoxy group or an ethylenically unsaturated group.

These polyfunctional or monofunctional (meth)acrylate compounds can used alone or in combination of two or more of them.

The above-described monofunctional (meth)acrylate having an epoxy group is obtained, for example, by making, under the presence of triphenylphosphine and tetrabutylammonium bromide, a polyfunctional group epoxy resin having at least two or more epoxy groups within one molecule to react with 0.1 to 0.9 equivalent weight of (rneth)acrylic acid relative to one equivalent weight of the epoxy groups. Furthermore, under the presence of dibutyltin dilaurate, a urethane (meth)acrylate containing a glycidyl group and the like are obtained by making a polyfunctional isocyanate compound to react with a (meth)acrylate containing a hydroxy group and an epoxy compound containing a hydroxy group or by making a polyfunctional epoxy resin to react with a (meth)acrylate containing an isocyanate group.

These (meth)acrylate compounds are preferably liquid at 25° C. at 1 atm, and furthermore, a 5% mass reduction temperature is preferably 120° C. or more. The % weight reduction temperature refers to a temperature at which 5% mass reduction is observed when a measurement is made through the use of a thermogravimetry differential thermal measurement device (manufactured by SII NanoTechnology Inc.: TG/DTA6300), at a temperature rise rate of 10° C./minute, under flow of nitrogen (400 ml/min). Through the use of these compound, it is possible to reduce foaming or contamination to peripheral members caused by volatilization in the thermal compression bonding or heating step.

Preferably, from the viewpoint of preventing the electromigration and corrosion of a metal conductor circuit, these (meth)acrylate compounds are highly pure in which alkali metal ions, alkaline earth metal ions and halogen ions that are impurity ions, especially chlorine ions, hydrolyzable chlorine and the like are reduced to 1000 ppm. For example, through the use of a polyfunctional epoxy resin, as a raw material, in which alkali metal ions, alkaline earth metal ions, halogen ions and the like are reduced, it is possible to satisfy the impurity ion concentration described above. The total chlorine content can be measured in accordance with JIS K7243-3.

Among them, the (meth)acrylate compounds described above preferably contain a monofunctional (meth)acrylate, and through the use of such a compound, it is possible to reduce, in being brought to a B-stage by exposure, the increase in cross-linking density caused by photopolymerization between (meth)acrylate groups. It is also possible to ensure good thermal compression bonding fluidity of the adhesive coating film after being brought to a B-stage, and it is possible to decrease the warpage of the adherend by reducing volume shrinkage after being brought to the B-stage.

From the viewpoint of ensuring intimate contact with the adherend after being brought to the B-stage, adhesion after the curing and heat resistance, the monofunctional (meth)acrylate described above preferably has an epoxy group, an urethane group, an isocyanurate group, an imide group or a hydroxyl group, and among them, a monofunctional (meth)acrylate having an imide group within the molecule and/or a monofunctional (meth)acrylate having an epoxy group within the molecule are/is preferably used. Because of this, it is possible to impart good adhesiveness to the surface of the adherends such as the semiconductor element and the supporting member and to further impart adhesiveness at high-temperature required in ensuring the reliability of the semiconductor device such as reflow resistance.

The amount of the monofunctional (meth)acrylate described above is preferably 20 to 100 weight %, more preferably 40 to 100 weight % and most preferably 50 to 100 weight %, of (A) the compound having a carbon-carbon double bond within the molecule. When the monofunctional (meth)acrylate described above has the blending amount described above, the intimate contact with the adherend and the thermal compression bonding after being brought to the B-stage are improved.

From the viewpoint of improving sensitivity, as (B) the photoinitiator, a photoinitiator in which its molecular extinction coefficient for light of a wavelength of 365 nm is 100 ml/g·cm or more is preferably used, and a photoinitiator in which its molecular extinction coefficient is 200 ml/g·cm or more is more preferably used. Meanwhile, the molecular extinction coefficient is determined by preparing a 0.01 weight % acetonitrile solution of the sample and measuring the absorbance of this solution through the use of a spectrophotometer (manufactured by Hitachi High-Technologies Corporation, “U-3310” (trade name)).

Examples of (B) the photoinitiator include aromatic ketones such as 2-benzyl-2-dimethylamino-1-(4-morpholino phenyl)-butanone-1,2,2-dimethoxy-1,2-diphenylethane-1-on, 1-hydroxy-cyclohexyl-phenyl-ketone, 2-methyl-1-(4-(methylthio) phenyl)-2-morpholinopropanone-1,2,4-diethylthioxanthone, 2-ethyl anthraquinone and a phenanthrenequinone; benzyl derivatives such as benzyl dimethyl ketal; 2,4,5-triarylimidazole dimers such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-phenylimidazole diner, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, and 2-(2,4-dimethoxyphenyl)-4,5-diphenyl imidazole dimer; acridine derivatives such as 9-phenyl acridine and 1,7-bis(9,9′-acridinyl)heptane; and compounds having a bisacylphosphine oxide and a maleimide such as bis(2,6-dimethoxybenzoyl)-2,4,4-trimethyl-pentylphosphine oxide and bis(2,4,6-trimethylbenzoyl)-phenylphosphine oxide. They can be used alone or in combination of two or more of them.

Among them, from the viewpoint of solubility in the adhesive composition that contains substantially no solvent, 2,2-dimethoxy-1,2-diphenylethane-1-on, 2-benzyl-2-dimethylamino-1-(4-morpholinophenyl)-butanone-1,2,2-dimethoxy-1,2-diphenylethane-1-on, and 2-methyl-1-(4-(methylthio) phenyl)-2-morpholinopropan-1-on are preferably used. In addition, from the viewpoint of the fact that it becomes possible to be brought to the B-stage, by exposure even under an atmosphere of air, 2-benzyl-2-dimethylamino-1-(4-morpholinophenyl)-butanone-1,2,2-di methoxy-1,2-diphenylethane-1-on, 2-methyl-1-(4-(methylthio)phenyl)-2-morpholinopropan-1-on are preferably used.

(B) the photoinitiator may contain a photoinitiator that produces the function of facilitating the polymerization and/or the reaction of epoxy resin by radiation irradiation. Examples of such photoinitiators include a photobase generator that generates a base by radiation irradiation and a photoacid generator that generates an acid by radiation irradiation, and the photobase generator is particularly preferable.

By using the photobase generator described above, it is possible to further enhance the high-temperature adhesion of the adhesive composition to the adherend and moisture resistance. This is probably because the base generated by the photobase generator effectively acts on the curing catalyst of the epoxy resin and thus it is possible to further enhance the cross-linking density, with the result that the curing catalyst is unlikely to corrode the substrate and the like. Moreover, when the photobase generator is contained within the adhesive composition, it is possible to enhance the cross-linking density and further reduce an outgassing during being left at a high temperature. Furthermore, it is probably possible to reduce the curing process temperature and the time needed for the curing process temperature.

As long as the photobase generator is a compound that generates a base at the time of irradiation, it can be used without being particularly limited. As the base generated, a strongly basic compound is preferable from the viewpoint of the reactivity and the curing rate.

Examples of such photobase generators that generate bases at the time of radiation irradiation include imidazole derivatives such as imidazole, 2,4-dimethyl imidazole and 1-methyl-imidazole, piperazine derivatives such as piperazine and 2,5-dimethyl piperazine, piperidine derivatives such as piperidine and 1,2-dimethyl-piperidine, proline derivatives, trialkyl amine derivatives such as trimethyl amine, triethyl amine and triethanol amine, pyridine derivatives in which an amino group or an alkylamino group is replaced at the position 4 such as 4-methylamino pyridine and 4-methyl amino pyridine, pyrrolidine derivatives such as pyrrolidine, and n-methylpyrrolidine, dihydropyridine derivatives, alicyclic amine derivatives such as triethylenediamine and 1,8-diazabiscyclo(5,4,0)undecene-1 (DBU), benzylamine derivatives such as benzyl methyl amine, benzyl dimethyl amine and benzyl diethyl amine, and the like.

As the above-described photobase generators that generate bases by radiation irradiation, for example, quaternary ammonium salt derivatives can be used which are disclosed in clauses 313 and 314, volume 12 (1999), Journal of Photopolymer Science and Technology and in clauses 170 to 176 (1999), volume 11, Chemistry of Materials. Since they generate strongly basic trialkyl amine by the irradiation with activation rays (radiation irradiation), they are suitable for curing epoxy resin.

As the photobase generator described above, carbamic acid derivatives can also be used that is disclosed in page 12925, volume 118 (1996), Journal of American Chemical Society and in page 795, volume 28 (1996), Polymer Journal.

Examples of the photobase generator that generates a base by the application of activation rays include oxime derivatives such as 2,4-dimethoxy-1,2-diphenylethane-1-on, 1,2-octanedione, 1-[4-(phenylthio)-, 2-(o-benzoyloxime)], ethanone and 1-[9-ethyl-6-(2-methylbenzoyl)-9H-carbazole-3-yl]-, 1-(o-acetyloxime); 2-benzyl-2-dimethylamino-1-(4-morpholinophenyl)-butanone-1,2,2-dim ethoxy-1,2-diphenylethane-1-on, 2-methyl-1-(4-(methylthio)phenyl)-2-morpholinopropan-1-on, 2-benzyl-2-dimethylamino-1-(4-morpholinophenyl)-butanone-1, hexaarylbisimidazole derivative (a substituent such as halogen, an alkoxy group, a nitro group, a cyano group may be substituted in a phenyl group) which are commercially available as a photoradical generator, a benzoisooxazolone derivative, and the like.

As the photobase generator described above, a compound in which a group for generating a base is introduced in the main chain and/or the side chain of a polymer may be used. In this case, as its molecular weight, from the viewpoint of adhesiveness, fluidity and heat resistance as the adhesive, the weight-average molecular weight thereof is preferably 1000 to 100000, and more preferably 5000 to 30000.

Since the photobase generator described above does not react with epoxy resin without exposure, it has significantly excellent storage stability at room temperature.

The amount of (B) photoinitiator is not particularly limited, but it is preferably 0.01 to 30 mass parts relative to 100 mass parts of (A) the compound having a carbon-carbon double bond.

As (C) the epoxy resin, an epoxy resin that includes at least two or more epoxy groups within the molecule is preferable; from the viewpoint of thermal compression bonding property, curing characteristics and the properties of a cured material, a glycidyl ether type epoxy resin of phenol is more preferable. Examples of such resins include a glycidyl ether of bisphenol A-type (AD-type, S-type or F-type), a glycidyl ether of hydrogenated bisphenol A-type, a glycidyl ether of ethylene oxide adduct bisphenol A-type, a glycidyl ether of propylene oxide adduct bisphenol A-type, a glycidyl ether of phenol novolak resin, a glycidyl ether of cresol novolak resin, a glycidyl ether of bisphenol A novolak resin, a glycidyl ether of naphthalene resin, a glycidyl ether of 3 functional type (or 4 functional type), a glycidyl ether of dicyclopentadiene phenol resin, a glycidyl ester of dimer acid, a glycidyl amine of 3 functional type (or 4 functional type), a glycidyl amine of naphthalene resin and the like. They can be used alone or in combination of two or more of them.

Preferably, From the viewpoint of preventing the electromigration and the corrosion of a metal conductor circuit, (C) the epoxy resin is highly pure in which alkali metal ions, alkaline earth metal ions and halogen ions which are impurity ions, especially chlorine ions, hydrolyzable chlorine and the like are reduced to 300 ppm or less.

(C) the epoxy resin is preferably liquid at a temperature of 25° C. at 1 atm, and furthermore, a 5% mass reduction temperature is preferably 150° C. or more. The 5% weight reduction temperature refers to a temperature at which 5% mass reduction is observed when a measurement is made, through the use of the thermogravimetry differential thermal measurement device (manufactured by SII NanoTechnology Inc.: TG/DTA6300), at a temperature rise rate of 10° C./minute and under flow of nitrogen (400 ml/min). Through the use of the epoxy resin in which the 5% weight reduction temperature is high, it is possible to reduce volatilization at the time of thermal compression bonding and thermal curing. Such thermosetting resin having heat resistance includes an epoxy resin having an aromatic group within the molecule. From the viewpoint of adhesion and heat resistance, in particular, a glycidyl amine of 3 functional type (or 4 functional type) or a glycidyl ether of bisphenol A-type (AD-type, S-type or F-type) is preferably used.

The amount of (C) epoxy resin is preferably 1 to 100 mass parts, and more preferably 2 to 50 mass parts, relative to 100 mass parts of (A) the compound having a carbon-carbon double bond within the molecule. When the amount exceeds 100 mass parts, the tack force after exposure tends to be increased. In contrast, when the amount is less than one mass part, it tends to be impossible to obtain sufficient thermal compression bonding property and high-temperature adhesion.

For the purpose of facilitating the curing of (C) the epoxy resin, a curing accelerator can be contained in the adhesive composition. As long as the curing accelerator is a compound that facilitates the curing/polymerization of the epoxy resin by heating, it is not particularly limited, and examples thereof include a phenolic compound, an aliphatic amine, an alicyclic amine, an aromatic polyamine, a polyamide, an aliphatic acid anhydride, an alicyclic anhydride, an aromatic acid anhydride, a dicyandiamide, an organic acid dihydrazide, a trifluoride boron amine complex, imidazoles, a dicyandiamide derivative, a dicarboxylic acid dihydrazide, triphenylphosphine, tetraphenyl phosphonium tetraphenyl borate, 2-ethyl-4-methylimidazole-tetraphenyl borate, 1,8-diazabicyclo[5,4,0]undecene-7-tetraphenyl borate, a tertiary amine and the like. Among them, from the viewpoint of solubility and dispersibility when containing no solvent, imidazoles are preferably used. The amount of curing accelerator is preferably 0.01 to 50 mass parts relative to 100 mass parts of the epoxy resin. Moreover, imidazoles are particularly preferable also from the viewpoint of adhesiveness, heat resistance and storage stability.

The reaction-starting temperature of the imidazoles described above is preferably 50° C. or more, more preferably 80° C. or more, and further preferably 100° C. or more. When the reaction-starting temperature is less than 50° C., the storage stability is reduced, and thus there is a possibility that the viscosity of the adhesive composition is increased and that it is difficult to control the film thickness.

The imidazoles described above are preferably compounds that are formed of particles each having an average diameter of preferably 10 μm or less, more preferably 8 μm or less, and most preferably 5 μm or less. By using the imidazoles each having the particle diameter described above, it is possible to suppress the change in the viscosity of the adhesive composition and to suppress the precipitation of the imidazoles. Moreover, when the thin adhesive layer is formed, projections and recesses in the surface are reduced, and thus it is possible to obtain a more uniform film. Furthermore, since, at the time of curing, the curing in the adhesive composition can be uniformly performed, and thus it is considered that outgassing can be reduced. Through the use of the imidazole having a low degree of solubility in the epoxy resin, it is possible to obtain good storage stability.

As the imidazoles, imidazoles that are soluble in epoxy resin can also be used. By using the such imidazoles, it is possible to more reduce projections and recesses in the surface at the time of the formation of the thin film. The imidazoles described above is preferably at least one selected from 2-ethyl-4-methylimidazole, 1-cyanoethyl-2-methylimidazole, 1-cyanoethyl-2-ethyl-4-methylimidazole, 1-cyanoethyl-2-phenylimidazole, 1-benzyl-2-methylimidazole and 1-cyanoethyl-2-phenylimidazolium trimellitate.

As the curing agent of (C) the epoxy resin, a phenol-based compound may be contained. The phenol-based compound having at least two or more phenol hydroxyl groups within the molecule is more preferable. Examples of such compounds include a phenol novolak, a cresol novolak, a t-butylphenol novolac, a dicyclopentadiene cresol novolak, a dicyclopentadiene phenol novolac, a xylylene modified phenol novolac, a naphthol compound, a trisphenol compound, a tetrakisphenol novolac, a bisphenol A novolac, a poly-p-vinylphenol, a phenol aralkyl resin and the like. Among them, a phenol compound having a number average molecular weight of 400 to 4000 is preferable. This makes it possible to suppress outgassing that contaminates the semiconductor element or device or the like at the time of heating in the assembly of the semiconductor device. The amount of the phenol-based compound is preferably 50 to 120 mass parts and is more preferably 70 to 100 mass parts relative to 100 mass parts of the thermosetting resin.

In addition to (C) the epoxy resin, the adhesive composition according to the present embodiment can contain, as necessary, a cyanate ester resin, a maleimide resin, an allylnadimide resin, a phenol resin, a urea resin, a melamine resin, an alkyd resin, an acrylic resin, an unsaturated polyester resin, a diallyl phthalate resin, a silicone resin, a resorcinol-formaldehyde resin, a xylene resin, a furan resin, a polyurethane resin, a ketone resin, a triallyl cyanurate resin, a polyisocyanate resin, a resin containing a tris(2-hydroxyethyl)isocyanurate, a resin containing a triallyl trimellitate, a thermosetting resin synthesized from a cyclopentadiene, a thermosetting resin obtained by trimerizing an aromatic dicyanamide or the like. Meanwhile, these thermosetting resins can be used alone or in combination of two or more of them.

In order to improve low stress, intimate contact with the adherend and thermal compression bonding property, the adhesive composition according to the present embodiment can also contain, as necessary, a thermoplastic resin such as a polyester resin, a polyether resin, a polyimide resin, a polyamide resin, a polyamide imide resin, a polyether imide resin, a polyurethane resin, a polyurethane imide resin, a polyurethane amide imide resin, a siloxane polyimide resin, a polyester imide resin, copolymers thereof, precursors thereof (such as polyamide acid), a polybenzoxazole resin, a phenoxy resin, a polysulfone resin, a polyether sulfone resin, a polyphenylene sulfide resin, a polyester resin, a polyether resin, a polycarbonate resin, a polyether ketone resin, a (meth)acrylate copolymer, a novolac-type resin, a phenol resin or the like.

From the viewpoint of reducing the viscosity of the adhesive composition according to the present embodiment and ensuring the thermal compression bonding property after being brought to the B-stage, the glass transition temperature (Tg) of the thermoplastic resins described above is preferably 150° C. or less, and the weight average molecular weight is preferably 5000 to 500000. The Tg described above means a main dispersion peak temperature when the thermoplastic resin is formed into a film. Through the use of a viscoelasticity analyzer “RSA-2” (trade name) manufactured by Rheometric Ltd., the viscoelasticity of the film-shaped thermoplastic resin was measured under the conditions of a film thickness of 100 μm, a temperature rise rate of 5° C./minute, a frequency of 1 Hz and measurement temperatures of −150 to 300° C., and the tan δ peak temperature around Tg was set to be the main dispersion peak temperature. The weight average molecular weight described above means a weight average molecular weight that is measured in terms of polystyrene, through the use of a high-performance liquid chromatography “C-R4A” (trade name) manufactured by Shimadzu Corporation.

The amount of thermoplastic resin described above is not particularly limited, but it is preferably 1 to 200 mass parts relative to 100 mass parts of (A) the compound having a carbon-carbon double bond within the molecule.

As the thermoplastic resin, a resin having an imide group is preferable from the viewpoint of ensuring high-temperature adhesiveness and heat resistance. Examples of the resins having imide groups include a polyimide resin, a polyamide imide resin, a polyether imide resin, a polyurethane imide resin, a polyurethane amide imide resin, a siloxane polyimide resin, a polyester imide resin and copolymers thereof.

For example, a polyimide resin can be obtained by performing a condensation reaction on a tetracarboxylic acid dianhydride and a diamine by a known method. That is, in an organic solvent, either in equal moles of the tetracarboxylic acid dianhydride and the diamine or by adjusting, as necessary, the composition ratio such that, relative to a total of 1.0 mole of the tetracarboxylic acid dianhydride, a total of 0.5 to 2.0 moles of the diamine is preferably used and a total of 0.8 to 1.0 mole is more preferably used, an addition reaction is performed at a reaction temperature of 80° C. or less and preferably at a temperature of 0 to 60° C. The order of addition of the individual components is arbitrary. As the reaction proceeds, the viscosity of the reaction solution is gradually increased and a polyamide acid that is a precursor of a polyimide resin is produced. In order to reduce the decrease in various properties of the resin composition, the tetracarboxylic acid dianhydride is preferably subjected to recrystallization refining processing by using acetic acid anhydride.

With respect to the composition ratio of the tetracarboxylic acid dianhydride and the diamine in the condensation reaction, when a total of the diamine exceeds 2.0 moles relative to a total of 1.0 mole of the tetracarboxylic acid dianhydride, the amount of polyimide oligomer of an amine end in the obtained polyimide resin tends to be increased, and the weight average molecular weight of the polyimide resin is reduced, with the result that various properties of the resin composition including heat resistance tend to be insufficient. In contrast, when a total of the diamine is less than 0.5 mole relative to a total of 1.0 mole of the tetracarboxylic acid dianhydride, the amount of polyimide resin oligomer of acid ends tends to be increased, and the weight average molecular weight of the polyimide resin is reduced, with the result that various properties of the resin composition including heat resistance tend to be decreased.

The polyimide resin can be obtained by performing ring-closing dehydration on the reactant (polyamide acid). The ring-closing dehydration can be performed by a heat ring-closure method executing heat processing, a chemical ring-closure method using a dehydrating agent or the like.

The tetracarboxylic acid dianhydride used as a raw material of the polyimide resin is not particularly limited, and examples thereof include pyromellitic dianhydride, 3,3′,4,4′-biphenyltetracarboxylic acid dianhydride, 2,2′,3,3′-biphenyltetracarboxylic acid dianhydride, 2,2-bis(3,4-dicarboxyphenyl)propane dianhydride, 2,2-bis(2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxylate phenyl)sulfone dianhydride, 3,4,9,10-perylenetetracarboxylic dianhydride, bis(3,4-dicarboxyphenyl)ether dianhydride, benzene-1,2,3,4-tetracarboxylic acid dianhydride, 3,4,3′,4′-benzophenone tetracarboxylic acid dianhydride, 2,3,2′,3′-benzophenone tetracarboxylic acid dianhydride, 3,3,3′,4′-benzophenone tetracarboxylic acid dianhydride, 1,2,5,6-naphthalene tetracarboxylic acid dianhydride, 1,4,5,8-naphthalene tetracarboxylic acid dianhydride, 2,3,6,7-naphthalene tetracarboxylic acid dianhydride, 1,2,4,5-naphthalene tetracarboxylic acid dianhydride, 2,6-dichloro naphthalene-1,4,5,8-tetracarboxylic acid dianhydride, 2,7-dichloro naphthalene-1,4,5,8-tetracarboxylic acid dianhydride, 2,3,6,7-tetrachloronaphthalene-1,4,5,8-tetracarboxylic acid dianhydride, phenanthrene-1,8,9,10-tetracarboxylic acid dianhydride, pyrazine-2,3,5,6-tetracarboxylic acid dianhydride, thiophene-2,3,5,6-tetracarboxylic acid dianhydride, 2,3,3′,4′-biphenyltetracarboxylic acid dianhydride, 3,4,3,4′-biphenyltetracarboxylic acid dianhydride, 2,3,2′,3′-biphenyltetracarboxylic acid dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylenebis(trimellitate anhydride), ethylenetetracarboxylic acid dianhydride, 1,2,3,4-butanetetracarboxylic acid dianhydride, decahydronaphthalene-1,4,5,8-tetracarboxylic acid dianhydride, 4,8-dimethyl-1,2,3,5,6,7-hexahydronaphthalene-1,2,5,6-tetracarboxylic acid dianhydride, cyclopentane-1,2,3,4-tetracarboxylic acid dianhydride, pyrrolidine-2,3,4,5-tetracarboxylic acid dianhydride, 1,2,3,4-cyclobutanetetracarboxylic acid dianhydride, bis(exo-bicyclo[2,2,1]heptane-2,3-dicarboxylic acid dianhydride, bicyclo-[2,2,2]-oct-7-en-2,3,5,6-tetracarboxylic acid dianhydride, 2,2-bis(3,4-dicarboxyphenyl)propane dianhydride, 2,2-bis[4-(3,4-dicarboxyphenyl)phenyl]propane dianhydride, 2,2-bis(3,4-dicarboxyphenyl)hexafluoropropane dianhydride, 2,2-bis[4-(3,4-dicarboxyphenyl)phenyl]hexafluoropropane dianhydride, 4,4-bis(3,4-dicarboxyphenoxy)diphenylsulfide dianhydride, 1,4-bis(2-hydroxyhexafluoroisopropyl)benzene bis(trimellitic anhydride), 1,3-bis(2-hydroxyhexafluoroisopropyl)benzene bis (trimellitic anhydride), 5-(2,5-dioxotetrahydrofuryl)-3-methyl-3-cyclohexene-1,2-dicarboxylic acid dianhydride, a tetrahydrofuran-2,3,4,5-tetracarboxylic acid dianhydride, tetracarboxylic acid dianhydride expressed by the following general formula (1) and the like. In the formula, a represents an integer of 2 to 20.

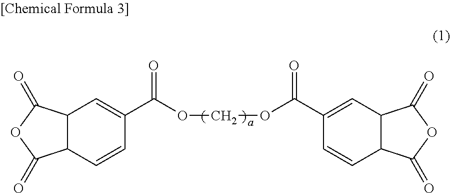

The tetracarboxylic acid dianhydride expressed by the above general formula (1) can be synthesized from, for example, a trimellitic anhydride monochloride and the corresponding diol. Examples of the tetracarboxylic acid dianhydride expressed by the formula (1) include 1,2-(ethylene)bis(trimellitate anhydride), 1,3-(trimethylene)bis(trimellitate anhydride), 1,4-(tetramethylene)bis(trimellitate anhydride), 1,5-(pentamethylene)bis(trimellitate anhydride), 1,6-(hexamethylene)bis(trimellitate anhydride), 1,7-(heptamethylene)bis(trimellitate anhydride), 1,8-(octamethylene)bis(trimellitate anhydride), 1,9-(nonamethylene)bis(trimellitate anhydride), 1,10-(decamethylene)bis(trimellitate anhydride), 1,12-(dodecamethylene)bis(trimellitate anhydride), 1,16-(hexadecamethylene)bis(trimellitate anhydride), 1,18-(octadecamethylene)bis(trimellitate anhydride) and the like.

From the viewpoint of imparting good solubility in a solvent and moisture resistance and transparency to light of 365 nm, tetracarboxylic acid dianhydride expressed by the following formula (2) or (3) is preferable.

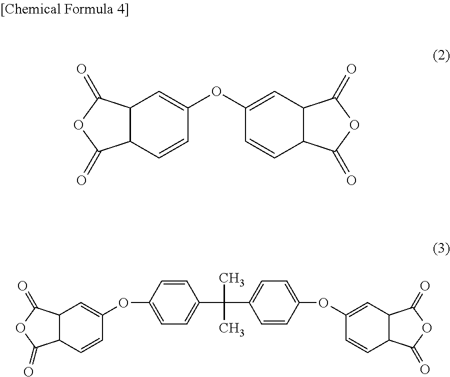

The tetracarboxylic acid dianhydrides described above can be used alone or in combination of two or more of them.

In the thermoplastic resin according to the present embodiment, from the viewpoint of further increasing the adhesion strength, a polyimide resin containing a carboxyl group and/or a phenolic hydroxyl group can be used. A diamine used as a raw material for this polyimide resin preferably contains an aromatic diamine expressed by the following formulas (4), (5), (6) or (7).

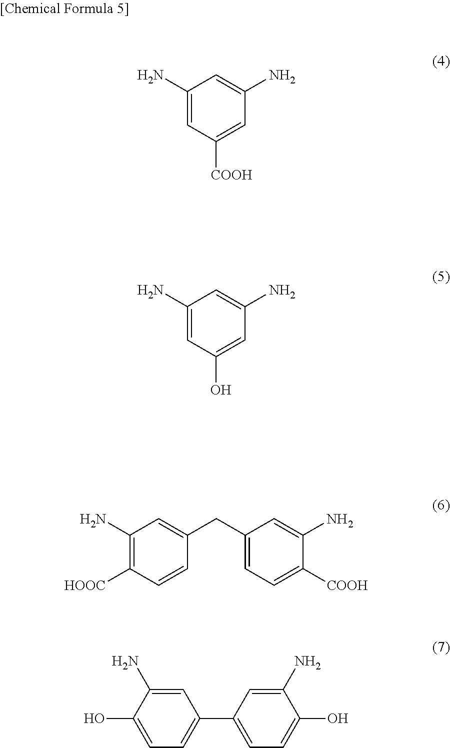

Other diamine used as the raw material for the polyimide resin described above is not particularly limited, and examples thereof include an aromatic diamine such as o-phenylenediamine, m-phenylenediamine, p-phenylenediamine, 3,3′-diaminodiphenylether, 3,4′-diaminodiphenylether, 4,4′-diaminodiphenylether, 3,3′-diaminodiphenylmethane, 3,4′-diaminodiphenylmethane, 4,4′-diaminodiphenylmethane, bis(4-amino-3,5-dimethylphenyl)methane, bis(4-amino-3,5-diisopropylphenyl)methane, 3,3-diaminodiphenyldifluoromethane, 3,4′-diaminodiphenyldifluoromethane, 4,4-diaminodiphenyldifluoromethane, 3,3′-diaminodiphenylsulfone, 3,4′-diaminodiphenylsulfone, 4,4′-diaminodiphenylsulfone, 3,3′-diaminodiphenyl sulfide, 3,4′-diaminodiphenylsulfide, 4,4′-diaminodiphenyl sulfide, 3,3′-diaminodiphenylketone, 3,4′-diaminodiphenylketone, 4,4′-diaminodiphenylketone, 2,2-bis(3-aminophenyl)propane, 2,2′-(3,4′-diaminodiphenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane, 2,2-bis(4-(3-aminophenoxy)phenyl)hexafluoropropane, 2,2-bis(4-(4-aminophenoxy)phenyl)hexafluoropropane, bis(4-(3-aminoenoxy)phenyl)sulfide, bis(4-(4-aminoenoxy)phenyl)sulfide, bis(4-(3-aminoenoxy)phenyl)sulfone, bis(4-(4-aminoenoxy)phenyl)sulfone, 3,3′-dihydroxy-4,4′-diaminobiphenyl, 3,5-diaminobenzoic acid; 1,3-bis(aminomethyl)cyclohexane, 2,2-bis(4-aminophenoxyphenyl)propane, an aliphatic ether diamine expressed by the following general formula (8), a siloxane diamine expressed by the following general formula (9) and the like.

Among the diamines described above, from the viewpoint of imparting compatibility with other components, an aliphatic ether diamine expressed by the following general formula (8) is preferable, and ethylene glycol based and/or propylene glycol based diamine is more preferable. In the following general formula (8), R¹, R² and R³ individually represent an alkylene group of 1 to 10 carbons and b represents an integer of 2 to 80.

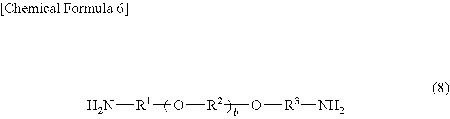

Specific examples of the aliphatic ether diamine described above include Jeffamine D-230, D-400, D-2000, D-4000, ED-600, ED-900, ED-2000 and EDR-148 manufactured by Sun Techono Chemical Co., Ltd.; polyether amines D-230, D-400 and D-2000 manufactured by BASF SE; and polyoxy alkylene diamines such as B-12 manufactured by Tokyo Chemical Industry Co., Ltd. and the like. The amount of each of these aliphatic ether diamines described above is preferably 20 or more mole % relative to all diamines, and is more preferably 50 or more mole % from the viewpoint of compatibility with other components having different compositions such as (A) the compound having a carbon-carbon double bond and (C) the epoxy resin, and from the viewpoint of the fact that thermal compression bonding property and high-temperature adhesion can be highly achieved at the same time.

As the diamine described above, from the viewpoint of imparting intimate contact and adhesion at room temperature, a siloxane diamine expressed by the following general formula (9) is preferable. In the following general formula (9), R⁴ and R⁹ individually represent an alkylene group of 1 to 5 carbons or a phenylene group that may have a substituent, R⁵, R⁶, R⁷ and R⁸ individually represent an alkylene group of 1 to 5 carbons, a phenyl group or a phenoxy group, and d represents an integer of 1 to 5.

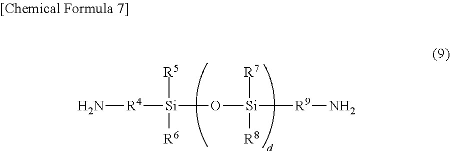

The amount of the siloxane diamine described above is preferably 0.5 to 80 mole % relative to all diamines, and is further preferably 1 to 50 mole % from the viewpoint of the fact that t thermal compression bonding property and high-temperature adhesion can be highly achieved at the same time. When the siloxane diamine is below 0.5 mole %, the effect caused by addition of the siloxane diamine is reduced, and when the siloxane diamine exceeds 80 mole %, compatibility with other components and high-temperature adhesion tend to be decreased.

Specific examples of the siloxane diamine expressed by the following general formula (9) where d represents 1 include 1,1,3,3-tetramethyl-1,3-bis(4-aminophenyl)disiloxane, 1,1,3,3-tetraphenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane and 1,3-dimethyl-1,3-dimethoxy-1,3-bis(4-aminobutyl)disiloxane; where d represents 2 include: 1,1,3,3,5,5-hexamethyl-1,5-bis(4-aminophenyl)trisiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane and 1,1,3,3,5,5-hexapropyl-1,5-bis(3-aminopropyl)trisiloxane.

The diamines described above can used alone or in combination of two or more of them.

Furthermore, the polyimide resins described above can used alone or in combination of two or more of them as necessary.

When the composition of the polyimide resin is determined, it is preferably designed such that the Tg thereof is 150° C. or less. As the diamine that is a raw material of the polyimide resin, an aliphatic ether diamine expressed by the general formula (8) is particularly preferably used.

At the time of the synthesis of the polyimide resin described above, a condensation reaction solution is charged with a monofunctional acid anhydride and/or a monofunctional amine such as a compound expressed by the following formula (10), (11) or (12), and thus it is possible to introduce, into polymer ends, a functional group other than an acid anhydride or a diamine. Furthermore, because of this, it is also possible to reduce the molecular weight of the polymer and the viscosity of the adhesive resin composition and improve the thermal compression bonding property.

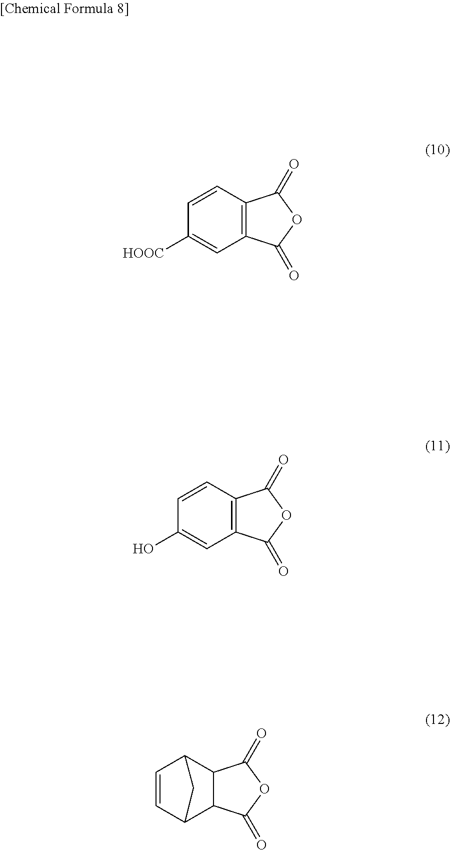

As the thermoplastic resin described above, from the viewpoint of suppressing the increase in viscosity and further reducing an undissolved residue in the resin composition, a liquid thermoplastic resin that is liquid at room temperature (25° C.) is preferably used. Since, in the thermoplastic resin described above, a reaction can be proceeded by heating without use of solvent, the thermoplastic resin is useful as the adhesive composition of the present invention using no solvent from the viewpoint of the decrease in the step of removal of the solvent, the reduction in the solvent left and the decrease in the precipitation step. The liquid thermoplastic resin can easily be removed from a reaction furnace. The liquid thermoplastic resin described above is not particularly limited. Examples of the liquid thermoplastic resin include rubber polymers such as polybutadiene, an acrylonitrile butadiene oligomer, polyisoprene and polybutene, polyolefin, an acrylic polymer, a silicone polymer, a polyurethane, a polyimide and a polyamide imide. Among them, a polyimide resin is preferably used.

The liquid polyimide resin, for example, can be obtained by making the acid anhydride described above to react with an aliphatic ether diamine or a siloxane diamine. As the method of synthesizing the liquid polyimide resin, it can be obtained by dispersing, without addition of solvent, the acid anhydride in an aliphatic ether diamine or a siloxane diamine and heating them.

The adhesive composition of the present embodiment can contain a sensitizer as necessary. Examples of the sensitizers include camphorquinone, benzyl, diacetyl, benzyl dimethyl ketal, benzyl diethyl ketal, benzyl (2-methoxyethyl) ketal, 4,4′-dimethyl benzyl-dimethyl ketal, anthraquinone, 1-chloroanthraquinone, 2-chloroanthraquinone, 1,2-benzanthraquinone, 1-hydroxyanthraquinone, 1-methylanthraquinone, 2-ethylanthraquinone, 1-bromoanthraquinone, thioxanthone, 2-isopropylthioxanthone, 2-nitrothioxanthone, 2-methylthioxanthone, 2,4-dimethylthioxanthone, 2,4-diethylthioxanthone, 2,4-diisopropylthioxanthone, 2-chloro-7-trifluoromethylthioxanthone, thioxanthone-10,10-dioxide, thioxanthone-10-oxide, a benzoin methyl ether, a benzoin ethyl ether, an isopropyl ether, a benzoin isobutyl ether, benzophenone, bis(4-dimethylaminophenyl)ketone, 4,4-bisdiethylaminobenzophenone and a compound containing an azido group. They can be used alone or in combination of two or more of them.

The adhesive composition of the present embodiment can contain a thermal radical generator as necessary. The thermal radical generator is preferably an organic peroxide. The one minute half-life temperature of the organic peroxide is preferably 80° C. or more, more preferably 100° C. or more, and most preferably 120° C. or more. The organic peroxide is selected in consideration of the preparation conditions of the adhesive composition, the film formation temperature, the curing (bonding) conditions, other process conditions, the storage stability and the like. The peroxide that can be used is not particularly limited, and examples thereof include 2,5-dimethyl-2,5-di(t-butylperoxyhexane), dicumyl peroxideide, t-butylperoxy-2-ethyl hexanoate, t-hexylperoxy-2-ethyl hexanoate, 1,1-bis(t-butylperoxy)-3,3,5-trimethylcyclohexane, 1,1-bis(t-hexylperoxy)-3,3,5-trimethylcyclohexane, bis(4-t-butylcyclohexyl)peroxy dicarbonate and the like. They can be used alone or by mixing two or more of them. Containing of the organic peroxide makes it possible to cause the compound having an unreacted carbon-carbon double bond remaining after exposure to react, and makes it possible to reduce outgassing and to enhance the adhesion.

The amount of the thermal radical generator is preferably 0.01 to 20 mass % relative to the compound having a carbon-carbon double bond, is further preferably 0.1 to 10 mass % and is most preferably 0.5 to 5 mass %. When the amount of thermal radical generator is less than 0.01 mass %, the curability is decreased, and thus the effects of the addition are reduced; when it exceeds 20 mass %, the amount of outgassing is increased, and thus the storage stability is decreased.

The thermal radical generator is not particularly limited as long as it is a compound whose half-life temperature is 80° C. or more. Examples thereof include, for example, Perhexa 25B (manufactured by NOF Corporation), 2,5-dimethyl-2,5-di(t-butylperoxyhexane) (one minute half-life temperature: 180° C.) Percumyl D (manufactured by NOF Corporation) and dicumyl peroxide (one minute half-life temperature: 175° C.).

In order to impart storage stability, process adaptability or oxidation prevention performance to the adhesive composition of the present embodiment, a polymerization inhibitor or an antioxidant such as quinones, polyhydric phenols, phenols, phosphites and sulfurs may be further added within the range not impairing the curability.

Furthermore, a filler can be contained in the adhesive composition of the present embodiment as necessary. Examples of the filler include metal fillers such as silver powder, gold powder, copper powder and nickel powder; inorganic fillers such as alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide, and ceramic; and organic fillers such as carbon and rubber fillers. The use of them is not particularly limited regardless of their types, shapes or the like.

The fillers described above can be selected and used according to the desired functions. For example, the metal fillers are added in order to provide the resin composition with electrical conductivity, thermal conductivity, thixotropy and the like; the nonmetal inorganic fillers are added in order to provide the adhesive layer with thermal conductivity, low-heat expandability, low moisture absorption and the like; the organic fillers are added in order to provide the adhesive layer with toughness and the like.

The metal fillers, the inorganic fillers and the organic fillers can be used alone or in combination of two or more of them. Among them, since electrical conductivity, thermal conductivity, low moisture absorption, insulation and the like that are required for the adhesive material of a semiconductor device can be provided, the metal fillers, the inorganic fillers and the insulating fillers are preferable. Among the organic fillers and the insulating fillers, since the dispersion over resin varnish is good and high adhesion can be provided when heated, the silica filler is more preferable.

In the fillers described above, it is preferable that the average particle diameter be 10 μm or less and that the maximum particle diameter be 30 μm or less, and it is more preferable that the average particle diameter be 5 μm or less and that the maximum particle diameter be 20 μm or less. When the average particle diameter exceeds 10 μm, and the maximum particle diameter exceeds 30 μm, the effect of enhancing the destructive toughness tends to be not sufficiently obtained. The lower limits of the average particle diameter and the maximum particle diameter are not particularly limited; in general, each of them is 0.001 μm or more.

The amount of the filler is determined according to the properties or functions provided; it is preferably 0 to 50 mass % relative to the total amount of adhesive composition, more preferably 1 to 40 mass % and further preferably 3 to 30 mass %. The amount of filler is increased, and thus it is possible to reduce the thermal expansion coefficient, reduce the moisture absorption and increase the coefficient of elasticity, with the result that it is possible to effectively enhance dicing (cutting with a dicer blade), wire bonding (ultrasonic efficiency) and adhesion strength when heated.

The amount of filler is increased more than necessary, and thus the viscosity tends to be increased and the thermal compression bonding tends to be degraded. Therefore, the amount of filler preferably falls within the range described above. The optimum fill content is determined such that the required properties are balanced. Mixing and kneading using the fillers can be performed by combining, as necessary, dispersing machines such as an agitator, a milling machine, a three-shaft roll and a ball mill that are normally used.

The adhesive composition of the present embodiment can contain various coupling agents in order to enhance interface coupling between different materials. Examples of the coupling agent include, for example, silane, titanium, aluminum-based coupling agents; among them, since it is effective, the silane-based coupling agent is preferable. A compound that has a thermosetting functional group such as an epoxy group or a radiation polymerization functional group such as methacrylate and/or acrylate is more preferable. The boiling point and/or decomposition temperature of the silane-based coupling agent described above is preferably 150° C. or more, more preferably 180° C. or more and further more preferably 200° C. or more. In other words, the silane-based coupling agent having a boiling point and/or decomposition temperature of 200° C. or more and having a thermosetting functional group such as an epoxy group or a radiation polymerization functional group such as methacrylate and/or acrylate is most preferably used. The amount of coupling agent described above is preferably 0.01 to 20 mass parts relative to 100 mass parts of the adhesive composition used in terms of its effects, the heat resistance and the cost.

In order to adsorb ion impurities and enhance the reliability of insulation when moisture is absorbed, an ion-capturing agent can be further added to the adhesive composition of the present embodiment. The ion capturing agent described above is not particularly limited. Examples thereof include, for example, a triazine thiol compound, a compound such as a phenolic reducing agent that is known as a copper damage prevention agent for preventing copper from being ionized and dissolved and powdered bismuth, antimony, magnesium, aluminum, zirconium, calcium, titanium, tin-based inorganic compounds and their mixtures. Specific examples, which are not particularly limited, include inorganic ion capturing agents manufactured by Toagosei Co., Ltd. such as IXE-300 (antimony-based), IXE-500 (bismuth-based), IXE-600 (antimony, bismuth-based mixture), IXE-700 (magnesium, aluminum-based mixture), IXE-800 (zirconium-based) and IXE-1100 (calcium-based). They can be used alone or by mixing two or more of them. The amount of ion capturing agent described above is preferably 0.01 to 10 mass parts relative to 100 mass parts of the adhesive composition in terms of the effects of the addition, the heat resistance, the cost and the like.

The adhesive composition contains, for example, a photoinitiator and a radiation polymerization compound. Preferably, the adhesive composition contains substantially no solvent.

As the photoinitiator, for example, a compound that produces a radical, an acid, a base or the like under light irradiation can be used. Among them, from the viewpoint of corrosion resistance such as migration, a compound that produces a radical and/or a base under light irradiation is preferably used. In particular, since heating processing after exposure is not necessary and high sensitivity is achieved, a compound that produces a radical is preferably used. The compound that produces an acid or a base under light irradiation has the function of facilitating the polymerization and/or the reaction of epoxy resin.

Examples of the compound that produces a radical include an aromatic ketone such as 2-benzyl-2-dimethylamino-1-(4-morpholinophenyl)-butanone-1,2,2-dim ethoxy-1,2-diphenylethane-1-on, 1-hydroxy-cyclohexyl-phenyl-ketone, 2-methyl-1-(4-(methylthio)phenyl)-2-morpholinopropane-1,2,4-diethylthioxanthone, 2-ethyl anthraquinone, phenanthrenequinone and the like, a benzyl derivative such as benzyl dimethyl ketal, a 2,4,5-triaryl imidazole dimer such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-phenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, 2-(2,4-dimethoxyphenyl)-4,5-diphenylimidazole dimer and the like, acridine derivatives such as 9-phenylacridine, 1,7-bis(9,9′-acridinyl)heptane and the like, bisacylphosphine oxides such as bis(2,6-dimethoxybenzoyl)-2,4,4-trimethyl-pentylphosphine oxide, bis(2,4,6-trimethylbenzoyl)-phenylphosphine oxide and the like, an oxime ester compound and a maleimide compound. They can be used alone or in combination of two or more of them.

Among the photoinitiators described above, in terms of solubility in the adhesive composition containing no solvent, 2,2-dimethoxy-1,2-diphenylethane-1-on, 2-benzyl-2-dimethylamino-1-(4-morpholinophenyl)-butanone-1,2,2-dim ethoxy-1,2-diphenylethane-1-on and 2-methyl-1-(4-(methylthio)phenyl)-2-morpholinopropan-1-on are preferably used. Since being brought to the B-stage can be performed by exposure even under an atmosphere of air, 2-benzyl-2-dimethylamino-1-(4-morpholinophenyl)-butanone-1,2,2-dim ethoxy-1,2-diphenylethane-1-on and 2-methyl-1-(4-(methylthio)phenyl)-2-morpholinopropan-1-on are preferably used.

When a compound that produces a base by exposure (photobase generator) is used, it is possible to further enhance the high-temperature adhesion of the adhesive composition to the adherend and moisture resistance. This is probably because: the base produced from the photobase generator effectively acts as a curing catalyst, and thus it is possible to further enhance the cross-linking density, and the produced curing catalyst is unlikely to corrode the substrate or the like. When the photobase generator is contained in the adhesive composition, it is possible to enhance the cross-linking density and reduce an outgassing when left at a high temperature. Furthermore, it is probably possible to reduce the curing process temperature and the time required therefor.

The photobase generator can be used without being particularly limited, as long as it is a compound that produces a base by radiation application. As the base produced, a strongly basic compound is preferable in terms of the reactivity and the curing rate. More specifically, the pKa value of the base produced by the photobase generator in water solution is preferably 7 or more, and more preferably 8 or more. In general, pKa is a logarithm of an acid dissociation constant that is an index for basicity.

Examples of the photobase generator produced by radiation application include, for example, an imidazole and imidazole derivatives such as 2,4-dimethyl imidazole, 1-methyl imidazole and the like, piperazine and piperazine derivatives such as 2,5-dimethypiperazine and the like, piperidine and a piperidine derivative such as 1,2-dimethyl piperidine and the like, trialkylamine derivatives such as trimethylamine, triethylamine, triethanolamine and the like, pyridine derivatives in which an amino group or an alkyl group substitutes at the position 4 such as 4-methylaminopyridine, 4-dimethylaminopyridine and the like, pyrrolidine and a pyrrolidine derivative such as n-methylpyrrolidine and the like, an alicyclic amine derivative such as 1,8-diazabiscyclo(5,4,0)undecene-1 (DBU) and the like, benzyl amine derivatives such as benzylmethylamine, benzyldimethylamine, benzyldiethylamine and the like, a proline derivative, triethylenediamine, a morpholine derivative, a primary alkylamine.

An oxime derivative that produces a primary amino group by application of active light rays, commercially available as photo radical generators such as 2-methyl-1-(4-(methylthio)phenyl)-2-morpholinopropan-1-on (manufactured by Ciba Specialty Chemicals Company, Irgacure 907), 2-benzyl-2-dimethylamino-1-(4-morpholinophenyl)-butanone-1 (manufactured by Ciba Specialty Chemicals Company, Irgacure 369) and 3,6-bis-(2-methyl-2-morpholino-propionyl)-9-N-octylcarbazole (manufactured by ADEKA Company, Optomer N-1414), a hexaarylbisimidazole derivative (a phenyl group may substitute for a substituent such as a halogen, an alkoxy group, a nitro group, a cyano group), a benzisoxazolone derivative, a carbamate derivative and the like can be used as the photoinitiator.

As an example of the radiation polymerizable compound, there is a compound that has an ethylenically unsaturated group. Examples of the ethylenically unsaturated group include a vinyl group, an allyl group, a propargylic group, a butenyl group, an ethynyl group, a phenylethynyl group, a maleimide group, a nadimide group and a (meth)acrylic group. In terms of reactivity, a (meth)acrylic group is preferable. The radiation polymerizable compound preferably contains a monofunctional (meth)acrylate. By adding the monofunctional (meth)acrylate, in particular, it is possible to reduce the cross-linking density at the time of the exposure for being brought to the B-stage, and to obtain good thermal compression bonding property, low stress and adhesion after exposure.

The 5% weight reduction temperature of the monofunctional (meth)acrylate is preferably 100° C. or more, more preferably 120° C. or more, further preferably 150° C. or more and further more preferably 180° C. or more. Here, the 5% weight reduction temperature of the radiation polymerizable compound (the monofunctional (meth)acrylate) is measured using the thermogravimetry differential thermal measurement device (manufactured by SII NanoTechnology Inc.: TG/DTA6300), at a temperature rise rate of 10° C./minute, under flow of nitrogen (400 ml/min). By using the monofunctional (meth)acrylate whose 5% weight reduction temperature is high, it is possible to reduce the volatilization of the unreacted monofunctional (meth)acrylate left after being brought to the B-stage at the time of the thermal compression bonding or the thermal curing.

The monofunctional (meth)acrylate is selected from, for example, a glycidyl group-containing (meth)acrylate, a phenol EO modified (meth)acrylate, a phenol PO-modified (meth)acrylate, a nonyl phenol EO-modified (meth)acrylate, a nonyl phenol PO-modified (meth)acrylate, a phenolic hydroxyl group-containing (meth)acrylate, a hydroxyl group-containing (meth)acrylate, an aromatic (meth)acrylate such as a phenylphenol glycidyl ether (meth)acrylate, a phenoxy ethyl (meth)acrylate and the like, an imide group-containing (meth)acrylate, a carboxyl group-containing (meth)acrylate, an isobornyl group-containing (meth)acrylate, a dicyclopentadienyl group-containing (meth)acrylate and an isobornyl (meth)acrylate.

From the viewpoint of intimate contact with the adherend after being brought to the B-stage, adhesion after the curing and heat resistance, the monofunctional (meth)acrylate preferably has at least one kind of functional group selected from a urethane group, an isocyanurate group, imide group and a hydroxyl group. In particular, the monofunctional (meth)acrylate having an imide group is preferable.

The monofunctional (meth)acrylate having an epoxy group can also be preferably used. From the viewpoint of storage stability, adhesiveness, the reduction of an outgassing and heat-resistant and moisture-resistant reliability, the 5% weight reduction temperature of the monofunctional (meth)acrylate having an epoxy group is preferably 150° C. or more, more preferably 180° C. or more and further preferably 200° C. or more. From the viewpoint of being capable of suppressing volatilization or the segregation on the surface due to heat drying at the time of film formation, the 5% weight reduction temperature of the monofunctional (meth)acrylate containing an epoxy group is preferably 150° C. or more, from the viewpoint of being capable of suppressing voids and the peeling-off resulting from an outgassing at the time of thermal curing, and the decrease in adhesiveness, the 5% weight reduction temperature is further preferably 180° C. or more and further more preferably 200° C. or more, and from the viewpoint of being capable of suppressing voids and the peeling-off due to the volatilization of an unreacted component at the time of reflow, the 5% weight reduction temperature is most preferably 260° C. or more. The monofunctional (meth)acrylate having an epoxy group preferably includes an aromatic ring. It is possible to obtain high heat resistance by using a polyfunctional epoxy resin having a 5% weight reduction temperature of 150° C. or more, as the raw material of the monofunctional (meth)acrylate.

Although the monofunctional (meth)acrylate containing an epoxy group is not particularly limited; examples thereof include glycidyl methacrylate, glycidyl acrylate, 4-hydroxybutyl acrylate glycidyl ether, 4-hydroxybutyl methacrylate glycidyl ether, and, a compound obtained by reacting a compound with a functional group that reacts with an epoxy group and an ethylenically unsaturated group, with a polyfunctional epoxy resin, and the like. The functional group that reacts with an epoxy group is not particularly limited; but examples thereof include an isocyanate group, a carboxyl group, a phenolic hydroxyl group, a hydroxyl group, an acid anhydride group, an amino group, a thiol group, an amide group and the like. These compounds can be used alone or in combination of two or more of them.

The monofunctional (meth)acrylate containing an epoxy group can be obtained, for example, by reacting a polyfunctional epoxy resin having at least two or more epoxy groups within one molecule with 0.1 to 0.9 equivalent of a (meth)acrylic acid relative to 1 equivalent of the epoxy group under the presence of triphenyl phosphine and tetrabutylammonium bromide. A glycidyl group-containing urethane (meth)acrylate or the like can be obtained by reacting a polyfunctional isocyanate compound with a hydroxy group-containing (meth)acrylate and a hydroxy group-containing epoxy compound, or reacting a polyfunctional epoxy resin with an isocyanate group-containing (meth)acrylate, under the presence of dibutyl tin dilaurate.

Furthermore, it is preferable to use, as the monofunctional (meth)acrylate containing an epoxy group, a high-purity one obtained by reducing impurity ions such as alkali metal ions, alkaline earth metal ions, halogen ions and especially chlorine ions, hydrolyzable chlorine and the like to 1000 ppm or less, in order to prevent electromigration and the corrosion of a metal conductor circuit. For example, a polyfunctional epoxy resin in which alkali metal ions, alkaline earth metal ions, halogen ions and the like are reduced is used as the raw material, and thus it is possible to satisfy the impurity ion concentration described above. All chlorine content can be measured according to TIS K7243-3.

The monofunctional (meth)acrylate component containing an epoxy group satisfying the heat resistance and the purity is not particularly limited. Examples thereof include ones that use, as their raw materials, a glycidyl ether of bisphenol A-type (or AD-type, S-type, F-type), a glycidyl ether of hydrogenated bisphenol A-type, a glycidyl ether of ethyleneoxide adduct bisphenol A-type or F-type, a glycidyl ether of propyleneoxide adduct bisphenol A-type or F-type, a glycidyl ether of phenol novolak resin, a glycidyl ether of cresol novolak resin, a glycidyl ether of bisphenol A novolak resin, a glycidyl ether of naphthalene resin, a glycidyl ether of 3 functional type (or 4 functional type), a glycidyl ether of dicyclopentadiene phenol resin, a glycidyl ester of dimer acid, a glycidyl amine of 3 functional type (or 4 functional type), a glycidyl amine of naphthalene resin and the like.

In particular, in order to improve thermal compression bonding property, low stress and adhesiveness, each of the number of epoxy groups and the number of ethylenically unsaturated groups is preferably three or less; in particular, the number of ethylenically unsaturated groups is preferably two or less. These compounds are not particularly limited, but compounds represented by the following general formulas (13), (14), (15), (16) or (17) are preferably used. In the following general formulas (13) to (17), R¹² and R¹⁶ represent a hydrogen atom or a methyl group, R¹⁰, R¹¹, R¹³ and R¹⁴ represent a divalent organic group and R¹⁵ to R¹⁸ represent an organic group having an epoxy group or an ethylenically unsaturated group.

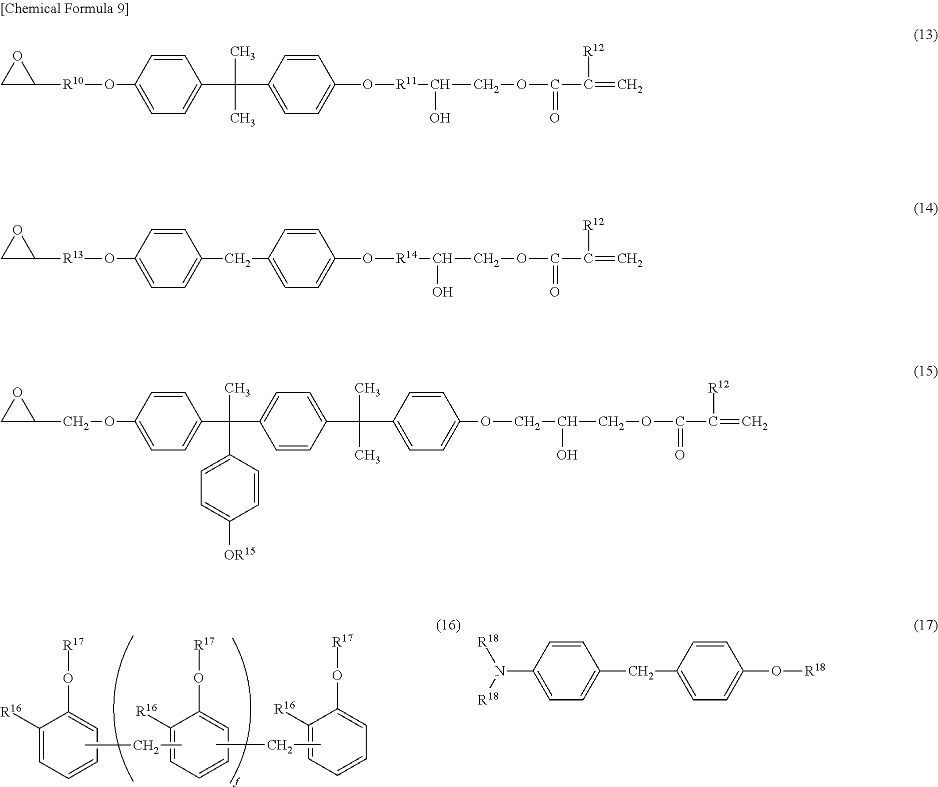

The amount of monofunctional (meth)acrylate described above is preferably 20 to 100 mass %, more preferably 40 to 100 mass % and most preferably 50 to 100 mass %, relative to the total amount of radiation polymerizable compound. When the amount of monofunctional (meth)acrylate falls within the range described above, it is possible to particularly enhance intimate contact with the adherend after being brought to the B-stage and thermal compression bonding property.

The radiation polymerizable compound may contain a two or more functional (meth)acrylate. The two or more functional (meth)acrylate is selected from, for example, diethylene glycol diacrylate, triethylene glycol diacrylate, tetraethylene glycol diacrylate, diethylene glycol dimethacrylate, triethylene glycol dimethacrylate, tetraethylene glycol dimethacrylate, trimethylolpropane diacrylate, trimethylol propane triacrylate, trimethylol propane dimethacrylate, trimethylol propane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, styrene, divinylbenzene, 4-vinyltoluene, 4-vinylpyridine, N-vinylpyrrolidone, 2-hydroxyethyl acrylate, 2-hydroxyethyl methacrylate, 1,3-acryloyloxy-2-hydroxyl propane, 1,2-methacryloyloxy-2-hydroxypropane, methylenebisacrylamide, N,N-dimethylacrylamide, N-methylol acrylamide, a triacrylate of tris(β-hydroxyethyl)isocyanurate, a compound expressed by the following general formula (18), a urethane acrylate or urethane methacrylate and an urea acrylate.

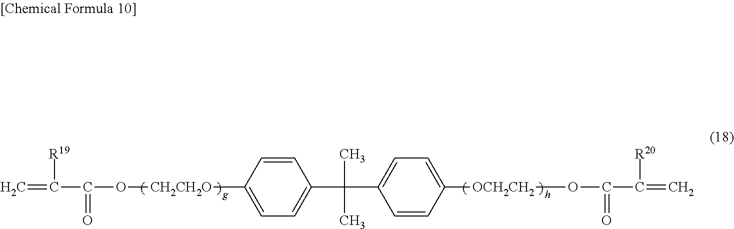

In the formula (18), R¹⁹ and R²⁰ individually represent a hydrogen atom or a methyl group, and g and h individually represent integers of 1 to 20.

These radiation polymerizable compounds can be used alone or in combination of two or more of them. Among them, since the radiation polymerizable compound expressed by the general formula (18) and having a glycol skeleton is preferable, since it can sufficiently provide solvent resistance after curing, and have a low viscosity and a high 5% weight reduction temperature.

Through the use of the radiation polymerizable compound having a high functional group equivalent weight, it is possible to reduce stress and warpage. The radiation polymerizable compound having a high functional group equivalent weight has a functional group equivalent weight of preferably 200 eq/g or more, more preferably 300 eq/g and most preferably 400 eq/g or more. By using the radiation polymerizable compound having a functional group equivalent weight of 200 eq/g or more and having an ether skeleton, a urethane group and/or an isocyanurate group, it is possible to enhance the adhesion of the adhesive composition and reduce stress and warpage. The radiation polymerizable compound having a functional group equivalent weight of 200 eq/g or more and the radiation polymerizable compound having a functional group equivalent weight of 200 eq/g or less may be used together.

The content of the radiation polymerizable compound is preferably 10 to 95 mass %, more preferably 20 to 90 mass % and most preferably 40 to 90 mass % relative to the total amount of adhesive composition. When the content of the radiation polymerization compound is more than 10 mass %, the tack force after being brought to the B-stage tends to be increased; when the content of the radiation polymerization compound is more than 95 mass %, the adhesion strength after the curing tends to be decreased.

The radiation polymerizable compound is preferably liquid at room temperature. The viscosity of the radiation polymerizable compound is preferably 5000 mPa·s or less, more preferably 3000 mPa·s or less, further preferably 2000 mPa·s or less, and most preferably 1000 mPa·s or less. When the viscosity of the radiation polymerizable compound is 5000 mPa·s or more, the viscosity of the adhesive composition tends to increase to make it difficult to prepare the adhesive composition, and to make it difficult to reduce the thickness of the film and make it difficult to perform discharge from the nozzle.

The 5% weight reduction temperature of the radiation polymerizable compound is preferably 120° C. or more, more preferably 150° C. or more and further preferably 180° C. or more. Here, the 5% weight reduction temperature of the radiation polymerizable compound is measured using the thermogravimetry differential thermal measurement device (manufactured by SIT NanoTechnology Inc.: TG/DTA6300), at a temperature rise rate of 10° C./minute, under flow of nitrogen (400 ml/min). By using the radiation polymerizable compound whose 5% weight reduction temperature is high, it is possible to reduce the volatilization of the unreacted radiation polymerization compound at the time of the thermal compression bonding or the thermal curing.

The adhesive composition preferably contains a thermosetting resin. As long as the thermosetting resin is a component formed with a reactive compound that causes a cross-linking reaction by heat, it is not particularly limited. The thermosetting resin is selected from, for example, an epoxy resin, a cyanate ester resin, a maleimide resin, an arylnadiimide resin, a phenol resin, a urea resin, a melamine resin, an alkyd resin, an acrylic resin, an unsaturated polyester resin, a diallyl phthalate resin, a silicone resin, a resorcinol-formaldehyde resin, an xylene resin, a furan resin, a polyurethane resin, a ketone resin, a triallyl cyanurate resin, a polyisocyanate resin, a resin containing a tris (2-hydroxyethyl)isocyanurate, a resin containing a triallyl trimellitate, a thermosetting resin synthesized from a cyclopentadiene and a thermosetting resin obtained by trimerizing a dicyanamide. Among them, since it is possible to have excellent adhesion strength at a high temperature, an epoxy resin, a maleimide resin and an arylnadiimide resin are preferable in the combination with a polyimide resin. The thermosetting resins can be used alone or in combination of two or more of them.

As the epoxy resin, a compound with two or more epoxy groups is preferable. In terms of thermal compression bonding property, curing property and the properties of a cured material, a phenol glycidyl ether type epoxy resin is preferable. Examples of this type of epoxy resin include, for example: a glycidyl ether of bisphenol A-type (or AD-type, S-type, F-type), a glycidyl ether of hydrogenated bisphenol A-type, a glycidyl ether of ethylene oxide adduct bisphenol A-type, a glycidyl ether of propylene oxide adduct bisphenol A-type, a glycidyl ether of phenol novolak resin, a glycidyl ether of cresol novolak resin, a glycidyl ether of bisphenol A novolak resin, a glycidyl ether of naphthalene resin, a glycidyl ether of 3 functional type (or 4 functional type), a glycidyl ether of dicyclopentadiene phenol resin, a glycidyl ester of dimer acid, a glycidyl amine of 3 functional type (or 4 functional type) and a glycidyl amine of naphthalene resin. These can be used alone or in combination of two or more of them.

Preferably, in order to reduce the electromigration and the corrosion of a metal conductor circuit, the epoxy resin is highly pure in which alkali metal ions, alkaline earth metal ions and halogen ions that are impurity ions, especially chlorine ions, hydrolyzable chlorine and the like are reduced to 300 ppm.

The content of the epoxy resin is preferably 1 to 100 mass parts, and more preferably 2 to 50 mass parts relative to 100 mass parts of the radiation polymerizable compound. When the content exceeds 100 mass parts, the tack after the exposure tends to be increased. In contrast, when the content is less than 2 mass parts, it tends to become difficult to obtain sufficient thermal compression bonding property and high-temperature adhesiveness.

The thermosetting resin is preferably liquid at room temperature. The viscosity of the thermosetting resin is preferably 10000 mPa·s or less, more preferably 5000 mPa·s or less, further preferably 3000 mPa·s or less and most preferably 2000 mPa·s or less. When the viscosity is 10000 mPa·s or more, the viscosity of the adhesive composition tends to be increased to make it difficult to reduce the thickness of the film.

The 5% weight reduction temperature of the thermosetting resin is preferably 150° C. or more, more preferably 180° C. or more and further preferably 200° C. or more. Here, the 5% weight reduction temperature of the thermosetting resin is measured using the thermogravimetry differential thermal measurement device (manufactured by SIT NanoTechnology Inc.: TG/DTA6300), at a temperature rise rate of 10° C./minute, under flow of nitrogen (400 ml/min). By using the thermosetting compound whose 5% weight reduction temperature is high, it is possible to reduce the volatilization at the time of the thermal compression bonding or the thermal curing. As the thermosetting resin that has such heat resistance, there is an epoxy resin that has an aromatic group. In terms of adhesiveness and heat resistance, in particular, a glycidyl amine of 3 functional type (or 4 functional type), a glycidyl ether of bisphenol A-type (or AD-type, S-type, F-type) is preferably used.

When the epoxy resin is used, the adhesive composition preferably contains a curing accelerator. As long as the curing accelerator is a compound that facilitates the curing/polymerization of the epoxy resin by heating, it is not particularly limited. The curing accelerator is selected from, for example, a phenolic compound, an aliphatic amine, an alicyclic amine, an aromatic polyamine, a polyamide, an aliphatic acid anhydride, an alicyclic acid anhydride, an aromatic acid anhydride, a dicyandiamide, an organic acid dihydrazide, a trifluorideboron amine complex, imidazoles, a dicyandiamide derivative, a dicarboxylic acid dihydrazide, triphenylphosphine, tetraphenylphosphonium tetraphenylborate, 2-ethyl-4-methylimidazole-tetraphenylborate, 1,8-diazabicyclo[5,4,0]undecene-7-tetraphenylborate and a tertiary amine. Among them, in terms of solubility and dispersibility when no solvent is contained, imidazoles are preferably used. The content of the curing accelerator is preferably 0.01 to 50 mass parts relative to 100 mass parts of the epoxy resin.

The reaction start temperature of the imidazoles is preferably 50° C. or more, more preferably 80° C. or more and further preferably 100° C. or more. When the reaction start temperature is 50° C. or less, the viscosity of the adhesive composition tends to increase and to make it difficult to control the film thickness, since the storage stability is reduced.

The imidazoles are preferably particles having an average diameter of preferably 10 μm or less, more preferably 8 μm or less and further preferably 5 μm or less. By using the imidazoles having the diameter of the particles described above, it is possible to suppress the change of the viscosity of the adhesive composition and to reduce the settling of the imidazoles. Moreover, when the thin film is formed, projections and recesses in the surface can be reduced to obtain a more uniform film. Furthermore, an outgassing can be reduced probably since the curing in the resin can be uniformly performed at the time of curing. When the imidazole having a low degree of solubility in the epoxy resin is used, it is possible to obtain good storage stability.

As the imidazoles, imidazoles that are soluble in epoxy resin can also be used. Through the use of the imidazoles described above, it is possible to further reduce projections and recesses in the surface when the thin film is formed. The imidazoles described above are not limited, but examples thereof include 2-ethyl-4-methylimidazole, 1-cyanoethyl-2-methylimidazole, 1-cyanoethyl-2-ethyl-4-methylimidazole, 1-cyanoethyl-2-phenylimidazole, 1-benzyl-2-methylimidazole, 1-benzyl-2-phenylimidazole and the like.

The adhesive composition may contain a phenol compound as the curing agent. As the phenol compound, a phenol compound that has at least two or more phenol hydroxyl groups within the molecule is more preferable. Examples of such compound include, for example, a phenol novolak, a cresol novolak, a t-butylphenol novolac, a dicyclopentadiene cresol novolak, a dicyclopentadiene phenol novolac, a xylylene modified phenol novolac, a naphthol-based compound, a tris phenol-based compound, a tetrakis phenol novolac, a bisphenol A novolac, a poly-p-vinylphenol and a phenol aralkyl resin. Among them, a phenol compound having a number average molecular weight of within a range of 400 to 4000 is preferable. Thus, it is possible to reduce an outgassing that contaminates the semiconductor element or device or the like at the time of heating in the assembly of the semiconductor device. The content of phenol compound is preferably 50 to 120 mass parts, and more preferably 70 to 100 mass parts relative to 100 mass parts of the thermosetting resin.

The maleimide resin used as the thermosetting resin is a compound that has two or more maleimide groups. Examples of the maleimide resin include a bismaleimide resin expressed by the following general formula (IV):

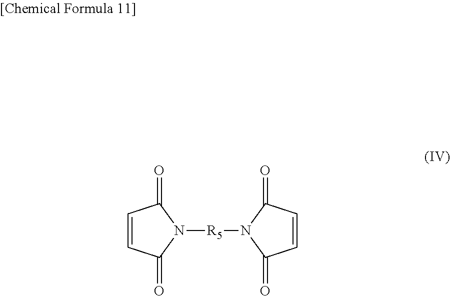

(in the formula, R₅ is a divalent organic group containing an aromatic ring and/or a linear, branched or cyclic aliphatic hydrocarbon group) and a novolak maleimide resin expressed by the following general formula (V):

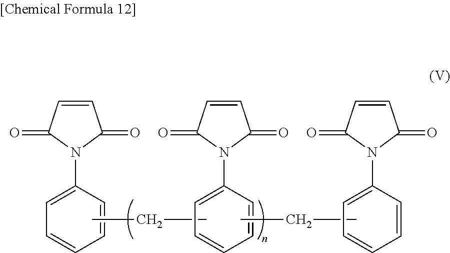

(in the formula, n represents an integer of 0 to 20)
In the formula (IV), R₅ is preferably a benzene residue, a toluene residue, a xylene residue, a naphthalene residue, a linear, branched or cyclic alkyl group or a mixed group thereof. More preferably, R₅ is a divalent organic group expressed by the following chemical formulas. In each of the formulas, n represents an integer of 1 to 10.

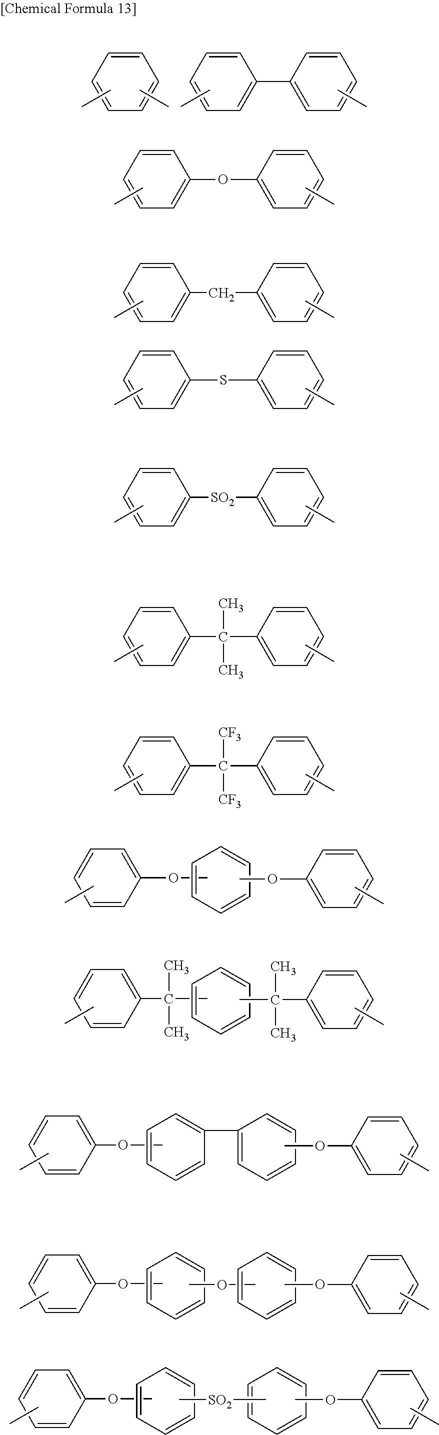

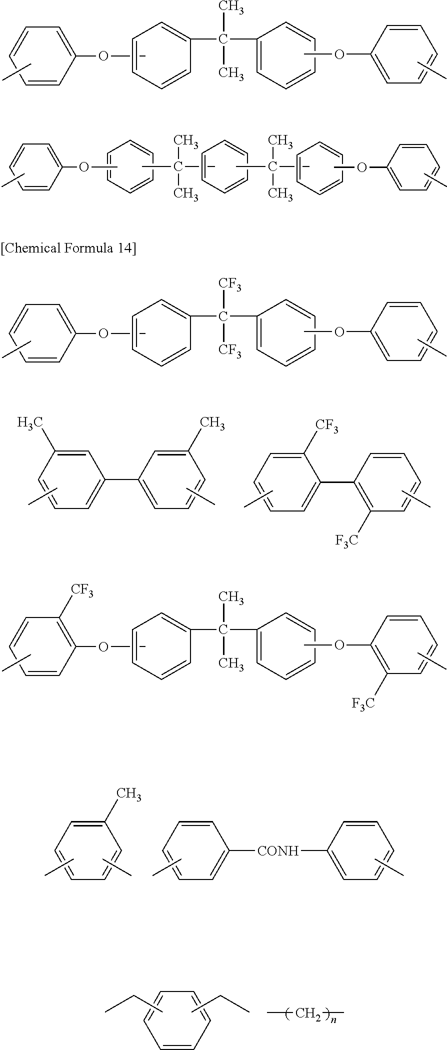

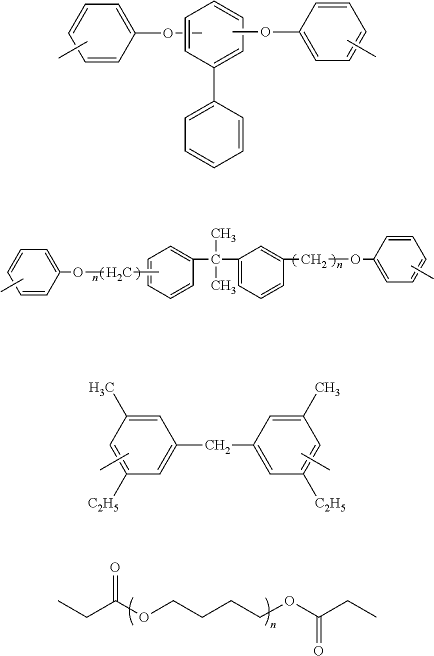

Among them, from the viewpoint of being capable of imparting heat resistance and high-temperature adhesiveness after curing, to the adhesion film, a bismaleimide resin having the following structure:

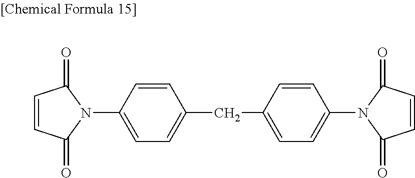

and/or a novolac-type maleimide resin having the following structure:

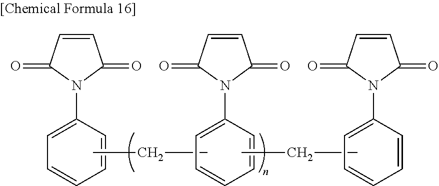

are preferably used. In the formulas, n represents an integer of 1 to 20.

In order to cure the maleimide resin above, an allyl bisphenol A, a cyanate ester compound may be combined with the maleimide resin. A catalyst such as a peroxide can be contained in the adhesive composition. The amount of compound added and the amount of catalyst added and whether or not they are added are adjusted as appropriate within a range in which the intended properties can be ensured.

The allylnadimide resin is a compound having two or more allylnadimide groups. As an example of the allylnadimide resin, there is a bisallylnadimide resin expressed by the following general formula (I).

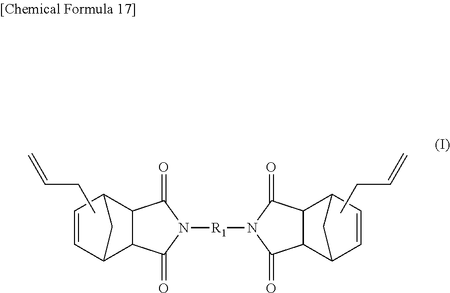

In the formula (1), R₁ represents a divalent organic group containing an aromatic ring and/or a linear, branched or cyclic aliphatic hydrocarbon group. R₁ is preferably a benzene residue, a toluene residue, a xylene residue, a naphthalene residue, a linear, branched or cyclic alkyl group or a mixed group thereof. More preferably, R₁ is a divalent organic group expressed by the following chemical formulas. In each of the formulas, n represents an integer of 1 to 10.

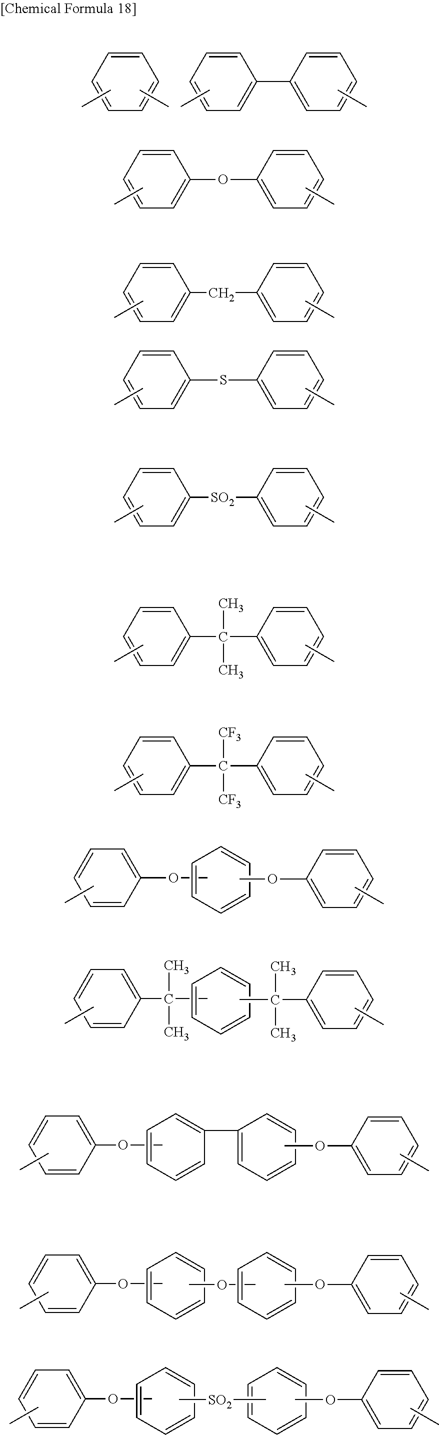

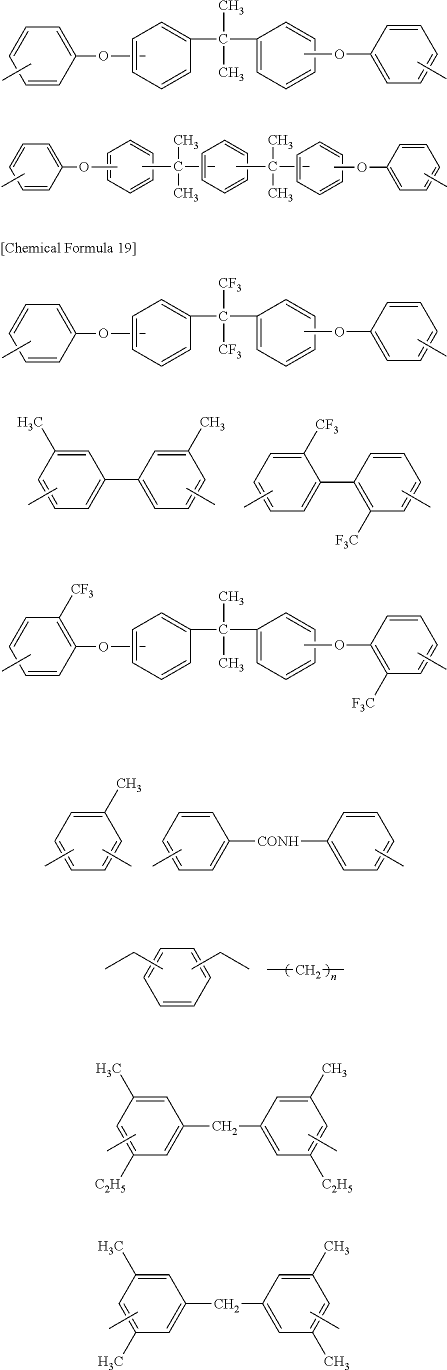

Among them, a liquid hexamethylene type bisallylnadimide expressed by the following chemical formula (II) and a solid xylylene type bisallylnadimide expressed by the following chemical formula (III) and having a low melting point (melting point: 40° C.) are preferable from the viewpoint that these can act also as a compatibilizing agent between different components constituting the adhesive composition and can impart good heat fluidity at the B-stage of the adhesion film. Furthermore, the solid xylylene type bisallylnadimide is more preferable, in addition to good heat fluidity, from the viewpoint of being capable of suppressing the increase in the stickiness of the surface of the film at room temperature, handling, easy peeling-off from a dicing tape at the time of pickup, and the suppression of re-fusion of a cutting surface after dicing.

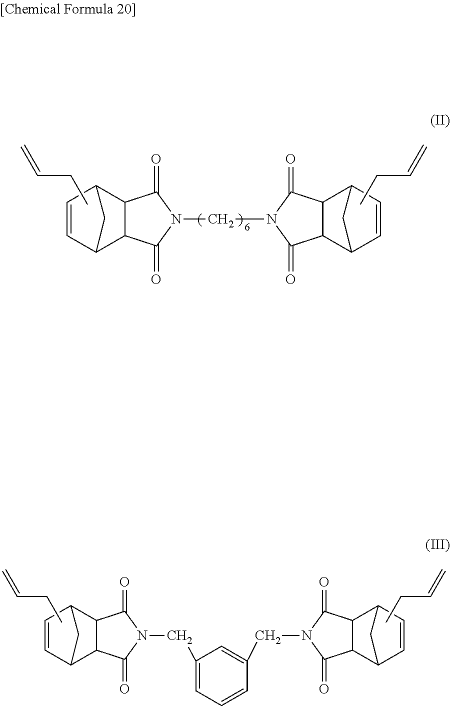

These bisallylnadimides can be used alone or in combination of two or more of them.

The allylnadimide resin requires a curing temperature of 250° C. or more, when cured solely without any catalyst. Furthermore, when a catalyst is used, only a metal corrosive catalyst such as a strong acid or onium salt which can be a serious fault in an electronic material is used, and a temperature of about 250° C. at final curing is required. In combined use of the allylnadimide resin above and any one of a two or more functional acrylate compound or methacrylate compound and a maleimide resin, it is possible to perform curing at a low temperature 200° C. or less (document: A. Renner, A. Kramer, “Allylnadic-imides; A New Class of Heat-Resistant Thermosets”, J. Polym. Sci., Part A Polym. Chem., 27, 1301 (1989).

The adhesive composition may further contain a thermoplastic resin. Through the use of the thermoplastic resin, it is possible to further enhance low stress, intimate contact with the adherend and thermal compression bonding property. The glass transition temperature (Tg) of the thermoplastic resin is preferably 150° C. or less, more preferably 120° C. or less, further more preferably 100° C. or less and most preferably 80° C. or less. When the Tg exceeds 150° C., the viscosity of the adhesive composition tends to increase. Moreover, it tends to be necessary to use a high temperature of 150° C. or more when the adhesive composition is thermal compression bonded to the adherend, and the semiconductor wafer tends to become easily warped.

Here, “Tg” means a main dispersion peak temperature of the thermoplastic resin formed into a film. Through the use of a viscoelasticity analyzer “RSA-2” (trade name) manufactured by Rheometric Ltd., the dynamic viscoelasticity of the film was measured under the conditions of a film thickness of 100 μm, a temperature rise rate of 5° C./minute, a frequency of 1 Hz and a measurement temperature of 0-150 to 300° C., and the main dispersion peak temperature of tan δ was set to Tg.

The weight average molecular weight of the thermoplastic resin is preferably within a range of 5000 to 500000, and more preferably within a range of 10000 to 300000 in that both thermal compression bonding property and high-temperature adhesiveness can be highly achieved at the same time. Here, the “weight average molecular weight” means a weight average molecular weight that is measured in terms of standard polystyrene through the use of a high-performance liquid chromatography “C-R4A” (trade name) manufactured by Shimadzu Corporation.

Examples of the thermoplastic resin include a polyester resin, a polyether resin, a polyimide resin, a polyamide resin, a polyamideimide resin, a polyether imide resin, a polyurethane resin, a polyurethane imide resin, a polyurethane amide imide resin, a siloxane polyimide resin, a polyester imide resin, copolymers thereof, precursors thereof (such as polyamide acid), a polybenzoxazole resin, a phenoxy resin, a polysulfone resin, a polyether sulfone resin, a polyphenylene sulfide resin, a polyester resin, a polyether resin, a polycarbonate resin, a polyether ketone resin, a (meth)acrylate copolymer having a weight average molecular weight of 10000 to 1000000, a novolac resin, a phenol resin and the like. These can be used alone or in combination of two or more of them. Furthermore, a glycol group such as an ethylene glycol or a propylene glycol, a carboxyl group and/or a hydroxyl group may be imparted to the main chain and/or the side chain of these resins.

Among them, the thermoplastic resin is preferably a resin having an imide group from the viewpoint of high-temperature adhesiveness and heat resistance. As the resin having an imide group, there is used at least one kind of resin selected, for example, from a group consisting of a polyimide resin, a polyamide imide resin, a polyether imide resin, a polyurethane imide resin, a polyurethane amide imide resin, a siloxane polyimide resin and a polyester imide resin.

For example, the polyimide resin can be synthesized by the following method. The resin can be obtained by performing a condensation reaction of tetracarboxylic acid dianhydride and a diamine by a known method. That is, in an organic solvent, either in equal moles of the tetracarboxylic acid dianhydride and the diamine or by adjusting, as necessary, the composition ratio such that a total of amine is preferably 0.5 to 2.0 moles and more preferably 0.8 to 1.0 mole relative to total 1.0 mole of the tetracarboxylic acid dianhydride, an addition reaction is performed at a reaction temperature of 80° C. or less and preferably at a temperature of 0 to 60° C. As the reaction proceeds, the viscosity of the reaction solution is gradually increased, and thus a polyamide acid that is a precursor of a polyimide resin is produced. Meanwhile, in order to suppress the decrease in the properties of the resin composition, the tetracarboxylic acid dianhydride described above is preferably subjected to recrystallization refining processing by using acetic acid anhydride.

With respect to the composition ratio of the tetracarboxylic acid dianhydride and the diamine in the condensation reaction, when a total of the diamine exceeds 2.0 moles relative to a total 1.0 mole of the tetracarboxylic acid dianhydride, the amount of polyimide oligomer at the amine end in the obtained polyimide resin tends to be increased, and the weight average molecular weight of the polyimide resin is reduced, with the result that various properties of the resin composition including heat resistance tends to become insufficient. In contrast, when the total of the diamine is less than 0.5 mole relative to a total 1.0 mole of the tetracarboxylic acid dianhydride, the amount of polyimide resin oligomer of acid ends tends to be increased, and the weight average molecular weight of the polyimide resin is reduced, with the result that various properties of the resin composition including heat resistance tend to be insufficient.

The polyimide resin can be obtained by performing ring-closing dehydration on the reactant (polyamide acid). The ring-closing dehydration can be performed such as by a heat ring-closure method using heat processing or a chemical ring-closure method using a dehydrating agent.

The tetracarboxylic acid dianhydride used as a raw material of the polyimide resin is not particularly limited, and examples thereof include pyromellitic acid dianhydride, 3,3′,4,4′-biphenyltetracarboxylic acid dianhydride, 2,2′,3,3′-biphenyltetracarboxylic acid dianhydride, 2,2-bis(3,4-dicarboxyphenyl)propane dianhydride, 2,2-bis (2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxyphenyl)sulfone dianhydride, 3,4,9,10-perylenetetracarboxylic acid dianhydride, bis(3,4-dicarboxyphenyl)ether dianhydride, benzene-1,2,3,4-tetracarboxylic acid dianhydride, 3,4,3′,4′-benzophenone tetracarboxylic acid dianhydride, 2,3,2′,3′-benzophenone tetracarboxylic acid dianhydride, 3,3,3′,4′-benzophenone tetracarboxylic acid dianhydride, 1,2,5,6-naphthalene tetracarboxylic acid dianhydride, 1,4,5,8-naphthalene tetracarboxylic acid dianhydride, 2,3,6,7-naphthalene tetracarboxylic acid dianhydride, 1,2,4,5-naphthalene tetracarboxylic acid dianhydride, 2,6-dichloronaphthalene-1,4,5,8-tetracarboxylic acid dianhydride, 2,7-dichloronaphthalene-1,4,5,8-tetracarboxylic acid dianhydride, 2,3,6,7-tetrachloronaphthalene-1,4,5,8-tetracarboxylic acid dianhydride, phenanthrene-1,8,9,10-tetracarboxylic acid dianhydride, pyrazine-2,3,5,6-tetracarboxylic acid dianhydride, thiophene-2,3,5,6-tetracarboxylic acid dianhydride, 2,3,3′,4′-biphenyltetracarboxylic acid dianhydride, 3,4,3,4′-biphenyltetracarboxylic acid dianhydride, 2,3,2′,3′-biphenyltetracarboxylic acid dianhydride, bis(3,4-dicarboxyphenyl)dimethylsllane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylenebis(trimellitate anhydride), ethylenetetracarboxylic acid dianhydride, 1,2,3,4-butanetetracarboxylic acid dianhydride, decahydronaphthalene-1,4,5,8-tetracarboxylic acid dianhydride, 4,8-dimethyl-1,2,3,5,6,7-hexahydronaphthalene-1,2,5,6-tetracarboxylic acid dianhydride, cyclopentane-1,2,3,4-tetracarboxylic acid dianhydride, pyrrolidine-2,3,4,5-tetracarboxylic acid dianhydride, 1,2,3,4-cyclobutane tetracarboxylic acid dianhydride, bis(exo-bicyclo[2,2,1]heptane-2,3-dicarboxylic acid dianhydride, bicyclo-[2,2,2]-oct-7-en-2,3,5,6-tetracarboxylic acid dianhydride, 2,2-bis(3,4-dicarboxyphenyl)propane dianhydride, 2,2-bis[4-(3,4-dicarboxyphenyl)phenyl]propane dianhydride, 2,2-bis(3,4-dicarboxyphenyl)hexafluoropropane dianhydride, 2,2-bis[4-(3,4-dicarboxyphenyl)phenyl]hexafluoropropane dianhydride, 4,4′-bis(3,4-dicarboxyphenoxy)diphenyl sulfide dianhydride, 1,4-bis(2-hydroxyhexafluoroisopropyl)benzene bis(trimellitic anhydride), 1,3-bis(2-hydroxyhexafluoroisopropyl)benzene bis(trimellitic anhydride), 5-(2,5-dioxotetrahydrofuryl)-3-methyl-3-cyclohexene-1,2-dicarboxylic acid dianhydride, tetrahydrofuran-2,3,4,5-tetracarboxylic acid dianhydride, and a tetracarboxylic acid dianhydride expressed by the following general formula (1) and the like. In the general formula (1), a represents an integer of 2 to 20.

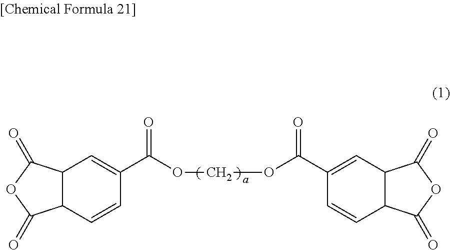

The tetracarboxylic acid dianhydride expressed by the above general formula (1) can be synthesized from, for example, a trimellitic anhydride monochloride and the corresponding diol. Examples thereof include 1,2-(ethylene)bis(trimellitate anhydride), 1,3-(trimethylene) bis(trimellitate anhydride), 1,4-(tetramethylene)bis(trimellitate anhydride), 1,5-(pentamethylene)bis(trimellitate anhydride), 1,6-(hexamethylene)bis(trimellitate anhydride), 1,7-(heptamethylene) bis(trimellitate anhydride), 1,8-(octamethylene)bis(trimellitate anhydride), 1,9-(nonamethylene)bis(trimellitate anhydride), 1,10-(decamethylene)bis(trimellitate anhydride), 1,12-(dodecamethylene)bis(trimellitate anhydride), 1,16-(hexadecamethylene)bis(trimellitate anhydride), 1,18-(octadecamethylene)bis(trimellitate anhydride) and the like.

Furthermore, from the viewpoint of imparting good solubility in a solvent and moisture resistance and transparency to light of 365 nm, to the tetracarboxylic acid dianhydride, a tetracarboxylic acid dianhydride expressed by the following general formula (2) or (3) is preferable.

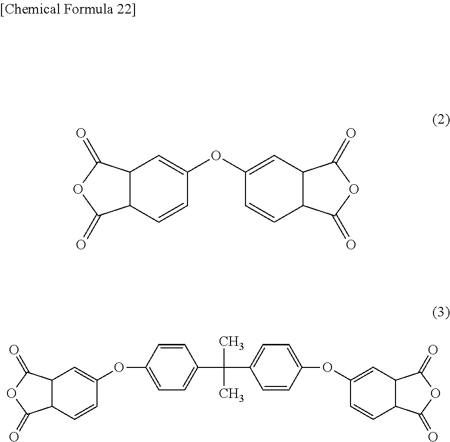

The tetracarboxylic acid dianhydrides described above can be used alone or in combination of two or more of them.

The diamine used as the raw material for the polyimide resin described above is not particularly limited, and examples thereof include, for example, an aromatic diamine such as o-phenylenediamine, m-phenylenediamine, p-phenylenediamine, 3,3′-diaminodiphenyl ether, 3,4′-diaminodiphenyl ether, 4,4′-diaminodiphenyl ether, 3,3-diaminodiphenylmethane, 3,4′-diaminodiphenylmethane, 4,4′-diaminodiphenyl ether methane, bis(4-amino-3,5-dimethylphenyl)methane, bis(4-amino-3,5-diisopropylphenyl)methane, 3,3-diaminodiphenyldifluoromethane, 3,4′-diaminodiphenyldifluoromethane, 4,4′-diaminodiphenyldifluoromethane, 3,3′-diaminodiphenylsulfone, 3,4′-diaminodiphenylsulfone, 4,4′-diaminodiphenylsulfone, 3,3′-diaminodiphenyl sulfide, 3,4′-diaminodiphenylsulfide, 4,4′-diaminodiphenyl sulfide, 3,3′-diaminodiphenyl ketone, 3,4′-diaminodiphenyl ketone, 4,4′-diaminodiphenyl ketone, 2,2-bis(3-aminophenyl)propane, 2,2′-(3,4′-diaminodiphenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl)propane, 2,2-bis(4-(3-aminophenoxy)phenyl)hexafluoropropane, 2,2-bis(4-(4-aminophenoxy)phenyl)hexafluoropropane, bis(4-(3-aminoenoxy)phenyl) sulfide, bis(4-(4-aminoenoxy)phenyl) sulfide, bis(4-(3-aminoenoxy)phenyl)sulfone, bis(4-(4-aminoenoxy)phenyl)sulfone, 3,3′-dihydroxy-4,4′-diaminobiphenyl, 3,5-diaminobenzoic acid and the like, 1,3-bis(aminomethyl)cyclohexane, 2,2-bis(4-aminophenoxyphenyl)propane, an aliphatic ether diamine expressed by the following general formula (8), a siloxane diamine expressed by the following general formula (9) and the like.

Among the diamines described above, from the viewpoint of imparting compatibility with other components to the diamines, an aliphatic ether diamine expressed by the following general formula (8) is preferable, and ethylene glycol-based and/or propylene glycol-based diamine is more preferable. In the following general formula (8), R¹, R² and R³ individually represent an alkylene group of 1 to 10 carbons and b represents an integer of 2 to 80.

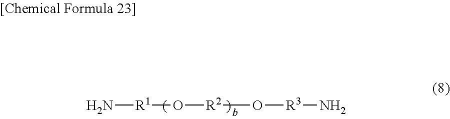

Specific examples of such aliphatic ether diamines include aliphatic diamines including polyoxy alkylene diamines such as Jeffamine D-230, D-400, D-2000, D-4000, ED-600, ED-900, ED-2000 and EDR-148 manufactured by Sun Techono Chemical Co., Ltd., and polyether amines D-230, D-400 and D-2000 manufactured by BASF SE. The amount of these diamines described above is preferably 20 or more mole % and more preferably 50 or more mole % relative to all diamines, from the viewpoint of the fact that compatibility with other components having different compositions, and thermal compression bonding property and high-temperature adhesiveness can be highly achieved at the same time.

As the diamine described above, in order to provide intimate contact and adhesiveness at room temperature, a siloxane diamine expressed by the following general formula (9) is preferable. In the following general formula (9), R⁴ and R⁹ individually represent an alkylene group of 1 to 5 carbons or a phenylene group that may have a substituent, R⁵, R⁶, R⁷ and R⁸ individually represent an alkylene group of 1 to 5 carbons, a phenyl group or a phenoxy group and d represents an integer of 1 to 5.

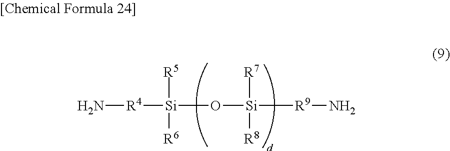

The content of the diamine described above is preferably 0.5 to 80 mole % relative to all diamines, and is further preferably 1 to 50 mole % from the point that a thermal compression bonding property and high-temperature adhesiveness can be highly achieved at the same time. When it is below 0.5 mole %, the effect produced by addition of the siloxane diamine becomes smaller, and when it exceeds 80 mole %, compatibility with other components and high-temperature adhesiveness tend to be decreased.

Specific examples of the siloxane diamines expressed by the following general formula (9) where d represents 1 include: 1,1,3,3-tetramethyl-1,3-bis(4-aminophenyl)disiloxane, 1,1,3,3-tetra phenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane, 1,3-dimethyl-1,3-dimethoxy-1,3-bis(4-aminobutyl)disiloxane and the like, where d represents 2 include: 1,1,3,3,5,5-hexamethyl-1,5-bis(4-aminophenyl)trisiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane, 1,1,3,3,5,5-hexapropyl-1,5-bis(3-aminopropyl)trisiloxane and the like.

The diamines described above can used alone or in combination of two or more of them.

The polyimide resins above can be used alone or by mixing two or more of them as necessary.

When the composition of the polyimide resin is determined, it is preferably designed such that Tg thereof is 150° C. or less. As the diamine that is a raw material of the polyimide resin, an aliphatic ether diamine expressed by the general formula (8) is particularly preferably used.

When the polyimide resin described above is synthesized, by putting a monofunctional acid anhydride and/or a monofunctional amine such as a compound expressed by the following formula (10), (11) or (12) into a condensation reaction solution, it is possible to introduce, into polymer ends, a functional group other than an acid anhydride or a diamine. Thus, it is also possible to reduce the molecular weight of the polymer and the viscosity of the adhesive resin composition and enhance the thermal compression bonding property.

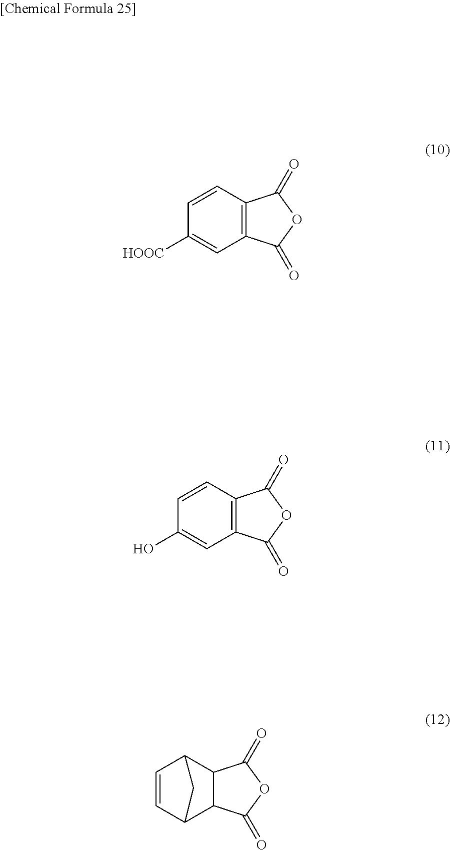

The thermosetting resin may have, in the main chain and/or the side chain thereof, a functional group such as an imidazole group having the function of facilitating the curing of epoxy resin. For example, a polyimide resin having an imidazole group can be obtained, for example, by a method using a diamine containing an imidazole group expressed by the following chemical formula as a part of a diamine used for synthesizing the polyimide resin.

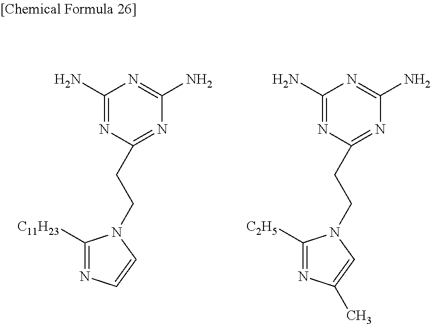

Since the uniform B-stage can be achieved, the transmittance of the polyimide resin above when it is formed into a film with a thickness of 30 μm with respect to 365 nm is preferably 10% or more, and since the B-stage with a low exposure amount can be achieved, it is further preferably 20% or more. Such polyimide resin can be synthesized by reacting, for example, the acid anhydride expressed by the general formula (2) described above with the aliphatic ether diamine expressed by the general formula (8) described above and/or the siloxane diamine expressed by the general formula (9) described above.

As the thermoplastic resin described above, from the point of suppressing the increase in viscosity and further reducing an undissolved residue in the adhesive composition, a thermoplastic resin that is liquid at room temperature (25° C.) is preferably used. By using such thermoplastic resin, the reaction can be performed by heating without use of solvent, and it is useful when the adhesive composition containing substantially no solvent, in terms of the decrease in the step of removal of the solvent, the reduction in the solvent left and the decrease in the precipitation step. The liquid thermoplastic resin can easily be removed from the reaction furnace. The liquid thermoplastic resin described above is not particularly limited. Examples of the liquid thermoplastic resin include: rubber polymers such as polybutadiene, an acrylonitrile butadiene oligomer, polyisoprene and polybutene, polyolefin, an acrylic polymer, a silicone polymer, polyurethane, a polyimide, a polyamide imide and the like. Among them, a polyimide resin is preferably used.

The liquid polyimide resin can be obtained, for example, by reacting the acid anhydride described above with an aliphatic ether diamine or a siloxane diamine. In the method of synthesizing the liquid polyimide resin, it can be obtained by dispersing, without addition of solvent, the acid anhydride in an aliphatic ether diamine or a siloxane diamine and heating them.

The adhesive composition of the present embodiment may contain a sensitizer as necessary. Examples of the sensitizer include, for example, camphorquinone, benzyl, diacetyl, benzyldimethyl ketal, benzyldiethyl ketal, benzyldi(2-methoxyethyl) ketal, 4,4′-dimethylbenzyl-dimethyl ketal, anthraquinone, 1-chloroarithraquinone, 2-chloroanthraquinone, 1,2-benzanthraquinone, 1-hydroxyanthraquinone, 1-methylanthraquinone, 2-ethylanthraquinone, 1-bromoanthraquinone, thioxanthone, 2-isopropylthioxanthone, 2-nitrothioxanthone, 2-methylthioxanthone, 2,4-dimethylthioxanthone, 2,4-diethylthioxanthone, 2,4-diisopropylthioxanthone 2-chloro-7-trifluoromethylthioxanthone, thioxanthone-10,10-dioxide, thioxanthone-10-oxide, a benzoin methyl ether, a benzoin ethyl ether, an isopropyl ether, a benzoin isobutyl ether, benzophenone, bis(4-dimethylaminophenyl)ketone, 4,4′-bis diethylaminobenzophenone and a compound containing an azido group. They can be used alone or in combination of two or more of them.

The adhesive composition of the present embodiment can contain a thermal radical generator as necessary. The thermal radical generator is preferably an organic peroxide. The one minute half-life temperature of the organic peroxide is preferably 80° C. or more, more preferably 100° C. or more and most preferably 120° C. or more. The organic peroxide is selected in consideration of the preparing conditions of the adhesive composition, the film formation temperature, the curing (sticking) conditions, other process conditions, the storage stability and the like. The peroxide that can be used is not particularly limited. Examples thereof include, for example, 2,5-dimethyl-2,5-di(t-butylperoxyhexane), dicumylperoxide, t-butylperoxy-2-ethylhexanoate, t-hexylperoxy-2-ethylhexanoate, 1,1-bis(t-butylperoxy)-3,3,5-trimethylcyclohexane, 1,1-bis(t-hexylperoxy)-3,3,5-trimethylcyclohexane, bis (4-t-butylcyclohexyl)peroxydicarbonate and the like. These can be used alone or by mixing two or more of them. When the organic peroxide is contained, it is possible to make react the radiation polymerizable compound that is left and does not react after exposure to reduce outgassing and to enhance the adhesion.

The amount of thermal radical generator added is preferably 0.01 to 20 mass %, further preferably 0.1 to 10 mass % and most preferably 0.5 to 5 mass %, relative to the total amount of the radiation polymerizable compound. When it is less than 0.01 mass %, the curing property is decreased, and thus the effects of the addition tend to be reduced; when it exceeds 5 mass %, the amount of outgassing tends to be increased, or the storage stability tends to be decreased.

The thermal radical generator is preferably a compound having a half-life temperature of 80° C. or more. Examples thereof include Perhexa 25B (manufactured by NOF Corporation), 2,5-dimethyl-2,5-di(t-butylperoxyhexane) (one minute half-life temperature: 180° C.), Percumyll D (manufactured by NOF Corporation) and dicumyl peroxide (one minute half-life temperature: 175° C.).

In order to provide storage stability, process adaptability or oxidation prevention, a polymerization inhibitor or an antioxidant such as quinones, polyhydric phenols, phenols, phosphites and sulfurs may be further added to the adhesive composition of the present embodiment as long as the curing property is not degraded.

A filler can be contained in the adhesive composition as necessary. Examples of the filler include, for example: metal fillers such as silver powder, gold powder, copper powder, nickel powder and tin; inorganic fillers such as alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide, and ceramic; and organic fillers such as carbon and rubber fillers. The use of them is not particularly limited regardless of their types, shapes or the like.

The fillers above can be selected and used according to the desired functions. For example, the metal fillers are added in order to impart electrical conductivity, thermal conductivity, thixotropy and the like to the resin composition, the nonmetal inorganic fillers are added in order to impart thermal conductivity, pickup property (easy peeling-off from a dicing tape), low-heat expandability, low moisture absorption and the like to the adhesive layer, and the organic fillers are added in order to impart toughness and the like to the adhesive layer.

The metal fillers, the inorganic fillers and the organic fillers can be used alone or in combination of two or more of them. Among them, since electrical conductivity, thermal conductivity, low moisture absorption, insulation and the like that are required for the adhesive material of a semiconductor device can be provided, the metal fillers, the inorganic fillers or the insulating fillers are preferable. Among the organic fillers or the insulating fillers, since the dispersion over resin varnish is good and high adhesion can be provided when heated, the silica filler is more preferable.

In the fillers described above, it is preferable that the average particle diameter is 10 μm or less and the maximum particle diameter is 30 μm or less, and it is more preferable that the average particle diameter is 5 μm or less and the maximum particle diameter is 20 μm or less. When the average particle diameter exceeds 10 μm and the maximum particle diameter exceeds 30 μm, the effect of enhancing the destructive toughness tends to be not sufficiently obtained. The lower limits of the average particle diameter and the maximum particle diameter are not particularly limited, but in general, each of them is 0.001 μm.

The amount of the filler contained is determined depending on the properties or functions imparted, and it is preferably 0 to 50 mass %, more preferably 1 to 40 mass % and further preferably 3 to 30 mass %, relative to the total amount of resin component and filler. By the increase in the amount of filler, it is possible to lower the alpha, reduce the moisture absorption and increase the coefficient of elasticity, with the result that it is possible to effectively enhance dicing property (cutting property with a dicer blade), wire bonding property (ultrasonic efficiency) and adhesion strength when heated.

If the amount of the filler is increased more than necessary, the viscosity tends to be increased and the thermal compression bonding property tends to be degraded. Therefore, the amount of the filler contained preferably falls within the range described above. The optimum filler content is determined such that the required properties are balanced. Mixing and kneading when using the fillers can be performed by combining, as necessary, dispersing machines such as an agitator, a milling machine, a three-shaft roll and a ball mill that are normally used.

Various coupling agents can be added to the adhesive composition in order to enhance interface coupling between different materials. Examples of the coupling agent include, for example, silane, titanium, aluminum-based coupling agents; among them, since it is effective, the silane-based coupling agent is preferable, and a compound having a thermosetting functional group such as an epoxy group or a radiation polymerizable functional group such as methacrylate and/or acrylate is more preferable. The boiling point and/or decomposition temperature of the silane-based coupling agent above is preferably 150° C. or more, more preferably 180° C. or more and further preferably 200° C. or more. In other words, the silane-based coupling agent having a boiling point and/or decomposition temperature of 200° C. or more and having a thermosetting functional group such as an epoxy group or a radiation polymerizable functional group such as methacrylate and/or acrylate is most preferably used. The amount of coupling agent above is preferably 0.01 to 20 mass parts relative to 100 mass parts of the adhesive composition used in terms of its effects, the heat resistance and the cost.

In order to adsorb ion impurities and enhance the reliability of insulation when moisture is absorbed, an ion capturing agent can be further added to the adhesive composition of the present embodiment. Such ion capturing agent is not particularly limited but it includes, for example, a triazine thiol compound, a compound such as a phenolic reducing agent that is known as a copper damage prevention agent for preventing copper from being ionized and dissolved, and powdered bismuth, antimony, magnesium, aluminum, zirconium, calcium, titanium, tin-based inorganic compounds and their mixtures. Specific examples, which are not particularly limited, include inorganic ion capturing agents manufactured by Toagosei Co., Ltd. such as IXE-300 (antimony-based), IXE-500 (bismuth-based), IXE-600 (antimony, bismuth-based mixture), IXE-700 (magnesium, aluminum-based mixture), IXE-800 (zirconium-based) and IXE-1100 (calcium-based). These can be used alone or by mixing two or more of them. The amount of the ion capturing agent above and used is preferably 0.01 to 10 mass parts relative to 100 mass parts of the adhesive composition in terms of the effects of the addition, the heat resistance, the cost and the like.

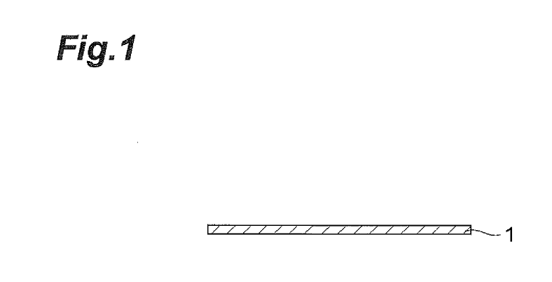

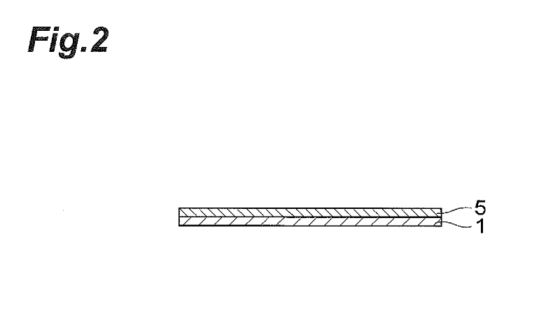

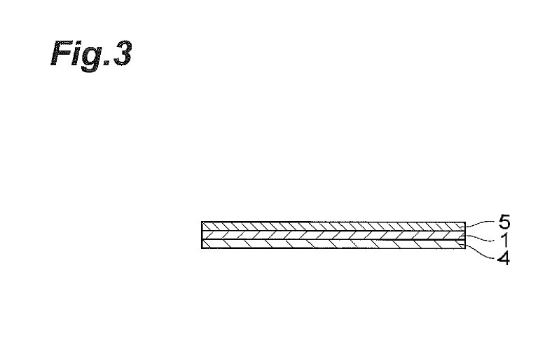

FIG. 1 is a cross-sectional view showing an embodiment of a semiconductor wafer; FIGS. 2 and 3 are cross-sectional views each showing an preferable embodiment of a semiconductor wafer with adhesive layer. The thickness of the adhesive layer 2 shown in FIGS. 2 and 3 is preferably 0.1 to 100 μm, more preferably 0.5 to 50 μm and further preferably 0.5 to 20 μm.

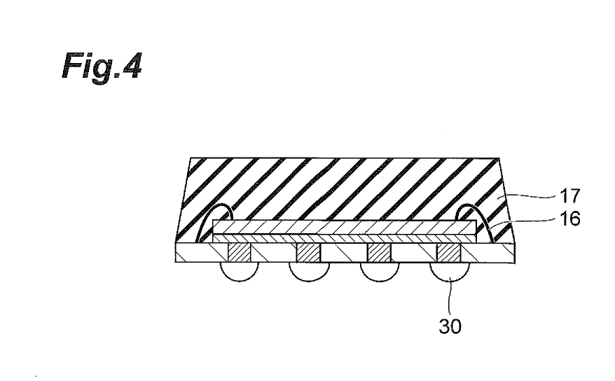

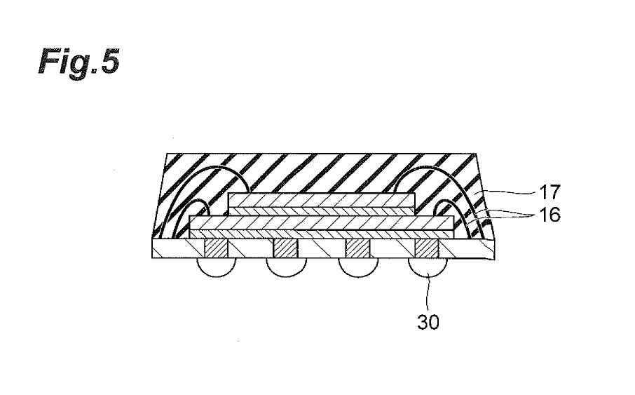

The semiconductor wafer shown in FIG. 3 includes a back grind tape 3, a semiconductor wafer 1 and the adhesive layer 2; they are stacked in this order. With the back grind tape 3 attached to the circuit surface of the semiconductor wafer 1, the coating film of the adhesive composition is formed on one surface of the semiconductor wafer 1 by a method such as a spin coat, and is then B-staged by exposure, and thus the adhesive layer 2 is formed. The semiconductor wafer with the adhesive layer configured as described above is suitably used for manufacturing, for example, a semiconductor device shown in FIGS. 4 and 5. The semiconductor manufacturing device shown in FIG. 4 includes one layer semiconductor chip adhered to a supporting member, and the semiconductor device shown in FIG. 5 includes two layer semiconductor chips adhered to each other via the adhesive layer. In these semiconductor devices, the semiconductor chips are connected to external connection terminals, and are sealed with a sealant 17. Solder balls 30 are provided on the bottom portion of the semiconductor device.

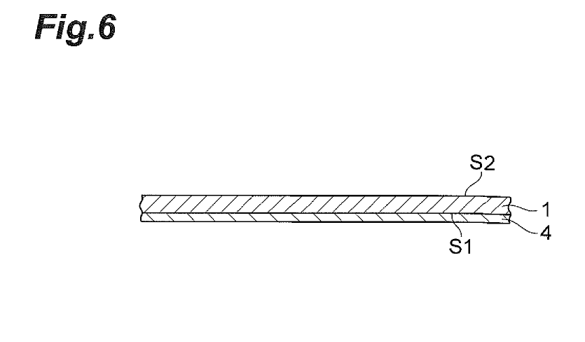

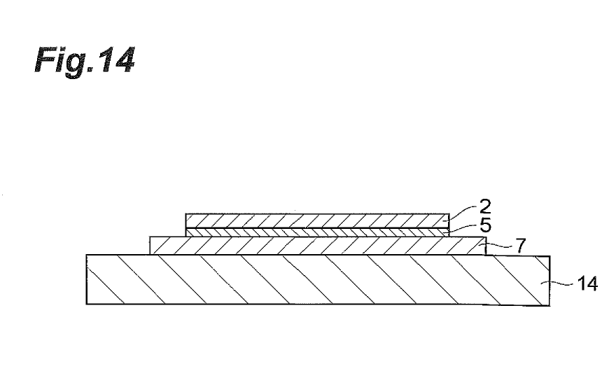

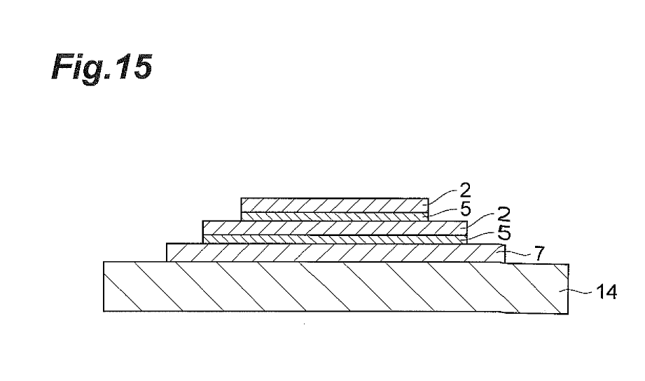

FIGS. 6 to 17 are schematic views showing an embodiment of a method for manufacturing the semiconductor device. The manufacturing method according to the present embodiment mainly includes the following steps.

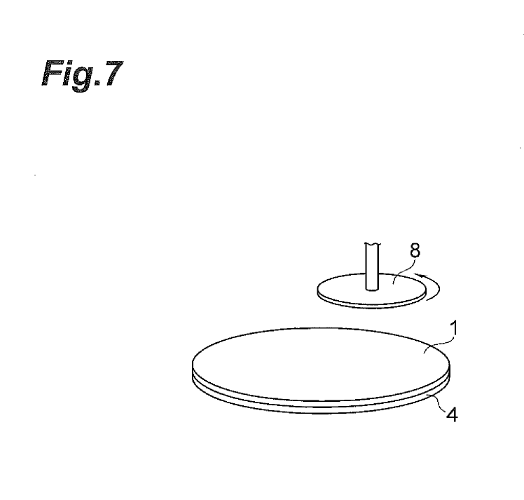

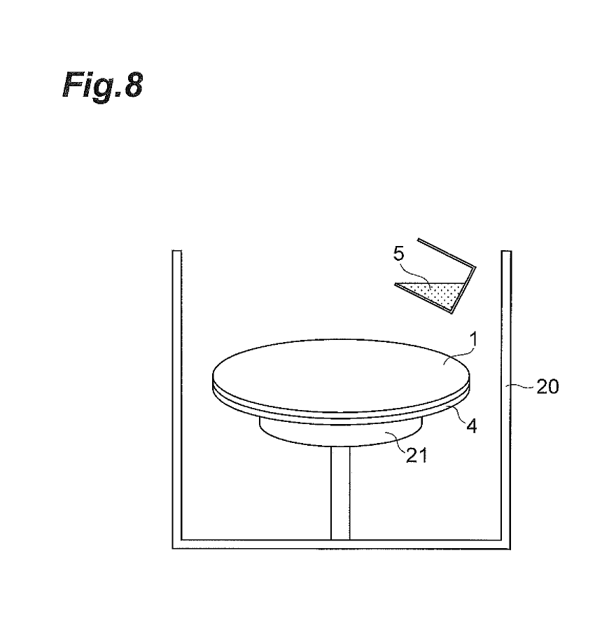

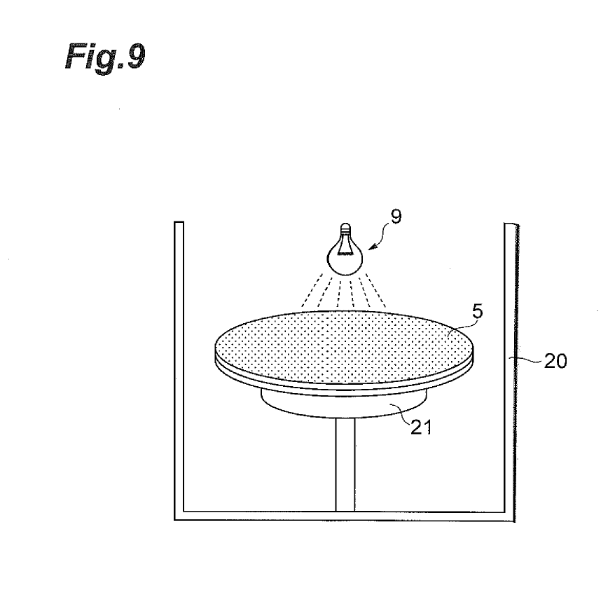

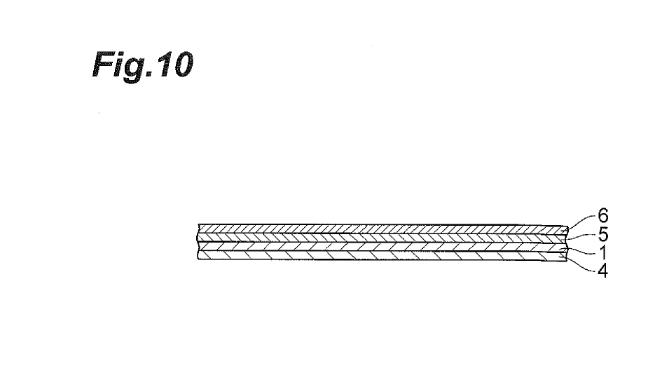

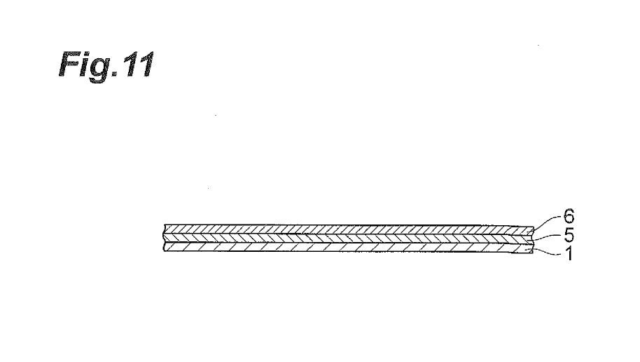

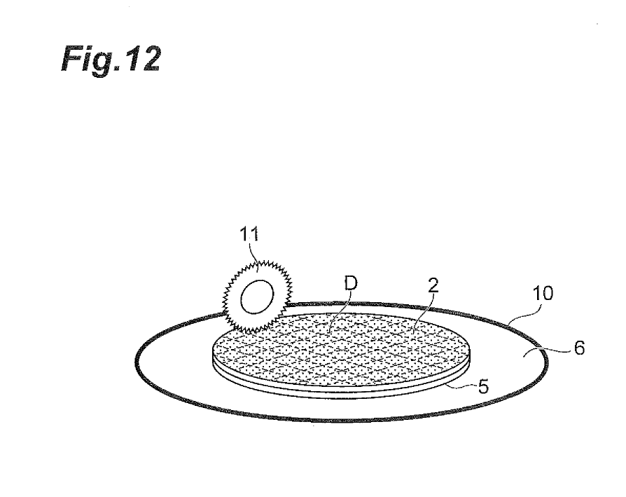

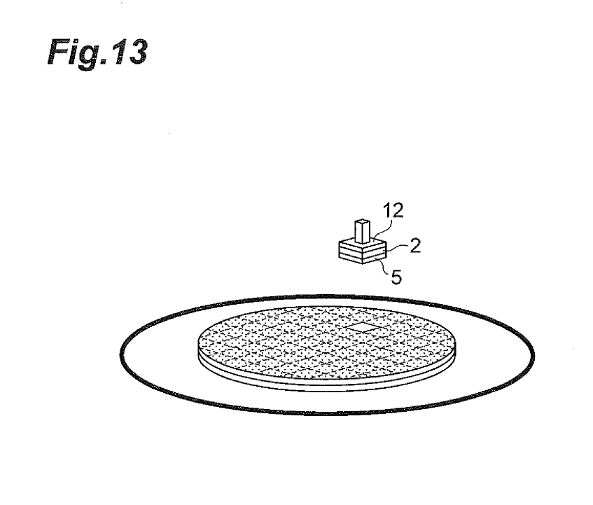

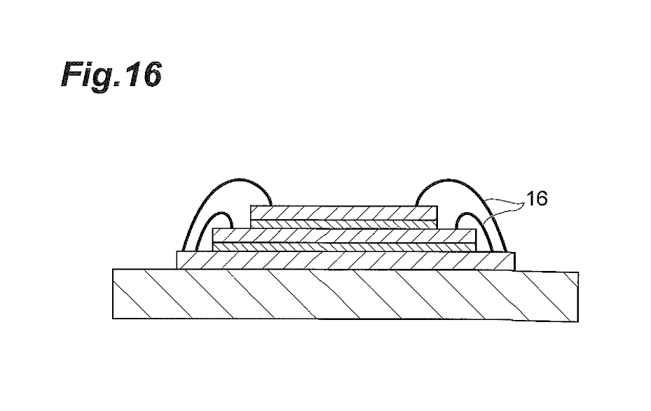

Step 1 (FIG. 6): an adhesive tape (back grind tape) 4 that can be peeled off is stacked on the circuit surface S1 of the semiconductor chip (semiconductor element) 2 formed within the semiconductor wafer 1.
Step 2 (FIG. 7): the semiconductor wafer 1 is decreased in thickness by being ground from the surface (rear face) S2 opposite to the circuit surface S1 of the semiconductor wafer 1.
Step 3 (FIG. 8): the adhesive composition 5 is applied on the rear face S2 of the semiconductor wafer 1.
Step 4 (FIG. 9): the adhesive composition is B-staged by performing exposure from the side of the adhesive layer 5 that is the applied adhesive composition.
Step 5 (FIG. 10): a pressure sensitive adhesive tape (dicing tape) 6 that can be peeled off is stacked on the adhesive layer 5.
Step 6 (FIG. 11): the dicing tape 6 is peeled off.
Step 7 (FIG. 12): the semiconductor wafer 1 is cut into a plurality of semiconductor chips 2 by dicing.
Step 8 (FIGS. 13, 14 and 15): the semiconductor chip 2 is picked up and compression bonded (mounted) on a semiconductor element mounting supporting member 7 or another semiconductor chip 2.
Step 9 (FIG. 16): the mounted semiconductor chip is connected to the external connection terminals on the supporting member 7 via wires 16.
Step 10 (FIG. 12): a stacked member including a plurality of semiconductor chips 2 is sealed with the sealant 17, and thus a semiconductor device 100 is obtained.

Step 1 (FIG. 6)

The back grind tape 4 is stacked on the side of the circuit surface S1 of the semiconductor wafer 1. The stacking of the back grind tape can be performed by a method of laminating a pressure sensitive adhesive tape that is previously formed in the form of a film.

Step 2 (FIG. 7)

The surface (rear face S2) opposite to the back grind tape 4 of the semiconductor wafer 1 is ground, and thus the thickness of the semiconductor wafer 1 is reduced to a predetermined thickness. The grinding is performed using a grind device 8 with the semiconductor wafer 1 fixed to a grind jig by the back grind tape 4.

Step 3 (FIG. 8)

After the grinding, the adhesive composition 5 is applied on the rear face S2 of the semiconductor wafer 1. The applying can be performed with the semiconductor wafer 1 to which the back grind tape 4 is bonded being fixed to the jig 21 within a box 20. The applying method is selected from a printing method, a spin coat method, a spray coat method, a gap coat method, a circle coat method, a jet dispense method, an inkjet method and the like. Among them, in order to reduce the thickness of the film and uniformly form the film thickness, the spin coat method and the spray coat method are preferable. A hole may be formed in an adsorption stage included in the spin coat device; the adsorption stage may be mesh-shaped. Since an adsorption mark is unlikely to be left, the adsorption stage is preferably mesh-shaped. In order to prevent the warpage of the wafer and the rising up of an edge portion, the coating by the spin coat method is preferably performed at a rotation speed of 500 to 5000 rpm. From the same point of view, the rotation speed is further preferably 1000 to 4000 rpm. In order to adjust the viscosity of the adhesive composition, a temperature adjuster can be provided on the spin coat stage.

The adhesive composition can be stored within a syringe. In this case, the temperature adjuster may be provided in the syringe set of the spin coat device.

When the adhesive composition is applied to the semiconductor wafer by, for example, the spin coat method, an unnecessary adhesive composition may adhere to the edge portion of the semiconductor wafer. Such an unnecessary adhesive can be removed by being washed with solvent or the like after the spin coat. The washing method is not particularly limited; a method of discharging solvent from a nozzle to a portion to which the unnecessary adhesive adheres while the semiconductor wafer is being spun is preferable. The solvent used for the washing is not limited as long as is dissolves the adhesive, for example, a low boiling solvent selected from methyl ethyl ketone, acetone, isopropyl alcohol and methanol is used.

The viscosity at 25° C. of the adhesive composition to be applied is preferably 10 to 30000 mPa·s, more preferably 30 to 10000 mPa·s, further preferably 50 to 5000 mPa·s, further more preferably 100 to 3000 mPa·s, and most preferably 200 to 1000 mPa·s. When the viscosity is 10 mPa·s or less, the storage stability of the adhesive composition tends to be reduced, and pinholes tend to be easily formed in the applied adhesive composition. It tends to be difficult to be brought to the B-stage by exposure. When the viscosity is 30000 mPa·s or more, it tends to be difficult to reduce the thickness of the film at the time of applying, and it tends to be difficult to perform the discharge. Here, the viscosity is a value that is measured at 25° C. through the use of an E-type viscometer.

Step 4 (FIG. 9)

By irradiating from the side of the adhesive layer 5 that is the applied adhesive composition, with activated light rays (typically ultraviolet rays) through the use of an exposure device 9, the adhesive composition is brought to a B-stage. Therefore, it is possible to fix the adhesive layer 5 to the semiconductor wafer 1 and to reduce tack of the surface of the adhesive layer 5. At this stage, the semiconductor wafer with adhesive layer according to the present embodiment is obtained. The exposure can be performed under the atmosphere of vacuum, nitrogen, air or the like. The exposure can also be performed in a state where a base material subjected to mold-releasing treatment such as a PET film or a polypropylene film is stacked on the adhesive layer 5, in order to reduce oxygen inhibition. The exposure can also be performed via a patterned mask. Through the use of the patterned mask, it is possible to form adhesive layers having a different fluidity at the time of thermal compression bonding. From the viewpoint of the reduction in tack and tact time, the amount of exposure is preferably 50 to 2000 mJ/cm².

The film thickness of the adhesive layer 5 after the exposure is preferably 30 μm or less, more preferably 20 μm or less, further preferably 10 μm or less and further more preferably 5 μm or less. The film thickness of the adhesive layer 5 after the exposure can be measured by, for example, the following method. First, the adhesive composition is applied onto the silicon wafer by spin coat (2000 rpm/10 s, 4000 rpm/20 s). The PET film subjected to mold-releasing treatment is laminated on the obtained coating film, and the exposure is performed at 1000 mJ/cm² through the use of the high precision parallel exposure device (“EXM-1172-B-∞” (trade name)) manufactured by ORC Manufacturing Co., Ltd. After that, the thickness of the adhesive layer is measured through the use of a surface roughness measuring device (manufactured by Kosaka Laboratory).

The tack force (surface tack force) of the surface of the adhesive layer at 30° C. after the exposure is preferably 200 gf/cm² or less. Because of this, the adhesive layer becomes highly excellent in terms of handing, ease of the dicing, and the pickup property after the exposure.

The tack force on the surface of the adhesive layer after the exposure is measured as follows. First, the adhesive composition is applied onto the silicon wafer by spin coat (2000 rpm/10 s, 4000 rpm/20 s), and the PET film subjected to mold-releasing treatment is laminated on the adhesive layer that is the applied adhesive composition, and the exposure is performed at 1000 mJ/cm² through the use of the high precision parallel exposure device (“EXM-1172-B-∞” (trade name)) manufactured by ORC Manufacturing Co., Ltd. After that, the tack force of the surface of the adhesive layer at a predetermined temperature (for example, 30° C.) is measured through the use of a probe tacking tester manufactured by Rhesca Corporation, under conditions in which the diameter of a probe is 5.1 mm, a peeling speed is 10 mm/s, a contact load is 100 gf/cm² and a contact time is 1 s.

When the tack force described above exceeds 200 gf/cm² at 30° C., the stickiness of the surface of the adhesive layer at room temperature becomes excessively increased and thus handing tends to be reduced. Moreover, problems tend to be easily caused in which water enters the interface between the adhesive layer and the adherend at the time of the dicing and thus chip flying occurs, and the peeling-off property from the dicing sheet after the dicing is reduced and thus the pickup property is lowered.

The 5% mass reduction temperature of the adhesive composition B-staged by the irradiation with light is preferably 120° C. or more, more preferably 150° C. or more, further preferably 180° C. or more, and further more preferably 200° C. or more. In order that the 5% mass reduction temperature is increased, it is preferable that the adhesive composition substantially contains no solvent. When the 5% mass reduction temperature is low, the adherend tends to be easily peeled off at the time of thermal curing after the compression bonding of the adherend or at the time of thermal history such as reflow, and thus it is necessary to perform heating and drying before the thermal compression bonding.

The 5% mass reduction temperature is measured as follows. The adhesive composition is applied onto the silicon wafer through by the spin coat (2000 rpm/10 s, 4000 rpm/20 s). The PET film subjected to mold-releasing treatment is laminated on the obtained coating film, and the exposure is performed at 1000 mJ/cm² through the use of the high precision parallel exposure device (“EXM-1172-B-∞” (trade name) manufactured by ORC Manufacturing Co., Ltd). After that, the 5% weight reduction temperature of the adhesive composition brought to a B-stage is measured through the use of the thermogravimetry differential thermal measurement device (manufactured by SII NanoTechnology Inc.: TG/DTA6300), at a temperature rise rate of 10° C./minute, under flow of nitrogen (400 ml/min).

Step 5 (FIG. 10)

After the exposure, the pressure sensitive adhesive tape 6 that can be peeled off, such as the dicing tape is stuck to the adhesive layer 5. The pressure sensitive adhesive tape 6 can be stuck by a method of laminating the pressure sensitive adhesive tape previously formed in the form of a film.

Step 6 (FIG. 11)

Then, the back grind tape 4 stuck to the circuit surface of the semiconductor wafer 1 is peeled off. For example, the adhesive tape whose stickiness is reduced by application of activated light rays (typically ultraviolet rays) is used, and the exposure is performed from the side of the back grind tape 4 and thereafter the back grind tape 4 can be peeled off.

Step 7 (FIG. 12)

Along a dicing line D, the semiconductor wafer 1 is cut together with the adhesive layer 5. By this dicing, the semiconductor wafer 1 is separated into a plurality of semiconductor chips 2 in which the adhesive layer 5 is provided on each back surface. The dicing is performed by using a dicing blade 11 with the whole semiconductor wafer fixed to a frame (wafer ring) by the pressure sensitive adhesive tape (dicing tape) 6.

Step 8 (FIGS. 13, 14 and 15)

After the dicing, the separated semiconductor chips 2 are picked up by a die bonding device 12 together with the adhesive layer 5, and are compression bonded (mounted) on the semiconductor device supporting member (supporting member for mounting the semiconductor element) 7 or another semiconductor chip 2. The compression bonding is preferably performed while being heated.

By the compression bonding, the semiconductor chips are made to adhere to the supporting member or another semiconductor chip. The shear strength at 260° C. between the semiconductor chips and the supporting member or another semiconductor chip is preferably 0.2 MPa or more, and more preferably 0.5 MPa or more. When the shear strength is less than 0.2 MPa, the peeling-off tends to be easily performed by thermal history such as a reflow step.

The shear strength here can be measured using a shearing adhesion power tester “Dage-400” (trade name). More specifically, for example, the measurement is performed by the following method. Exposure is first performed on the entire surface of the adhesive layer that is the adhesive composition applied to the semiconductor wafer, and then 3×3 square semiconductor chips are obtained by cutting. The semiconductor chips with the adhesive layer obtained by cutting are placed on a previously prepared 5×5 square semiconductor chip, and are compression bonded for two seconds at 120° C. while being pressurized at 100 gf. Thereafter, they are heated in an oven for one hour at 120° C. and then for three hours at 180° C., with the result that a sample in which the semiconductor chips are made to adhere to each other are obtained. The shear strength of the obtained sample at 260° C. is measured using the shearing adhesion power tester “Dage-400” (trade name).

Step 9 (FIG. 16)

After the step 8, each of the semiconductor chips 2 is connected to the external connection terminal on the supporting member 7 via the wire 16 connected to the bonding pad.

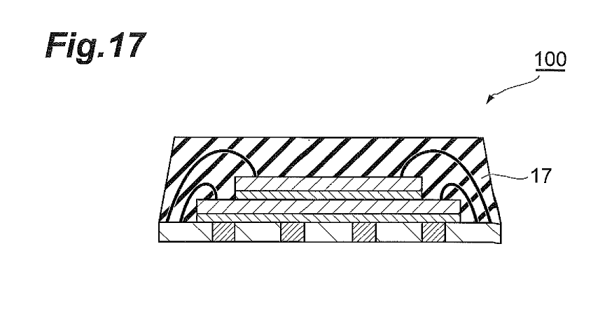

Step 10 (FIG. 17)

The stacked member including the semiconductor chips 2 is sealed with the sealant 17, and thus the semiconductor device 100 can be obtained.

By performing the steps described above, it is possible to manufacture the semiconductor device having a structure in which the semiconductor elements and/or the semiconductor element and the supporting member for mounting the semiconductor element are made to adhere. The structure of the semiconductor device and the method for manufacturing it are not limited to the embodiment described above; modifications are possible as appropriate without departing from the spirit of the present invention.

For example, the order of steps 1 to 7 can be changed as necessary. More specifically, the adhesive composition is applied to the back surface of the semiconductor wafer that is previously diced, and thereafter the adhesive composition can be B-staged by application of activated light rays (typically ultraviolet rays). Here, a patterned mask can be used.

Before or after the exposure, the applied adhesive composition may be heated to 120° C. or less, preferably to 100° C. or less and more preferably to 80° C. or less. In this way, the solvent and water left can be reduced, and thus it is possible to more reduce the tack after the exposure.

The 5% weight reduction temperature of the adhesive composition that has been B-staged by irradiation with light and then cured by heating is preferably 260° C. or more. When the 5% weight reduction temperature is 260° C. or less, the peeling-off tends to easily occur by the thermal history such as the reflow step.

The amount of outgassing from the adhesive composition that has been B-staged by irradiation with light and thereafter further cured by heating for one hour at 120° C. and then for three hours at 180° C. is preferably 10% or less, more preferably 7% or less and further preferably 5% or less. When the amount of outgassing is 10% or more, voids and the peeling-off tend to easily occur at the time of thermal curing.

The outgassing is measured as follows. The adhesive composition is applied onto the silicon wafer by spin coat (2000 rpm/10 s, 4000 rpm/20 s). The PET film subjected to mold-releasing treatment is laminated on the obtained coating film, and the exposure is performed at 1000 mJ/cm² with the high precision parallel exposure device (“EXM-1172-B-∞” (trade name)) manufactured by ORC Manufacturing Co., Ltd. Thereafter, the amount of outgassing is measured when the adhesive composition brought to a B-stage is heated according to a program in which the temperature is raised to 120° C. at a temperature rise rate of 50° C./minute, held for one hour at 120° C., further raised to 180° C. and is then held for three hours at 180° C., under flow of nitrogen (400 ml/min) using the thermogravimetry differential thermal measurement device (manufactured by SIT NanoTechnology Inc.: TG/DTA6300).

### EXAMPLE

The present invention will be specifically described below using examples. However, the present invention is not limited to the following examples.

<Thermoplastic Resin (Polyimide Resin)>

(PI-1)

In a flask provided with a stirrer, a thermometer, and a nitrogen substitution device, 5.72 g (0.02 mole) of MBAA, 13.57 g (0.03 mole) of “D-400”, 2.48 g (0.01 mole) of 1,1,3,3-teramethyl-1,3-bis(3-aminoplopyl)disiloxane (trade name “BY16-871EG” manufactured by Dow Corning Toray Co., Ltd.) and 8.17 g (0.04 mole) of 1,4-butanediolbis(3-aminopropyl)ether (trade name “B-12” manufactured by Tokyo Keiki Inc.; molecular weight: 204. 31), which are diamines and 110 g of NMP as a solvent were loaded and then these diamines were dissolved in the solvent by stirring.

While cooling the flask above in an ice bath, 29.35 g (0.09 mole) of 4,4′-oxydiphthalic acid dianhydride (hereinafter referred to as “ODPA”) and 3.84 g (0.02 mole) of TAA (trimellitic anhydride) which are acid hydrides were added in small amounts to the solution in the flask. After finishing the addition, stirring was performed at room temperature for 5 hours. Thereafter, a reflux condenser with a water receptor was attached to the flask, 70.5 g of xylene was added, the temperature of the solution was raised to 180° C. while blowing a nitrogen gas, which was kept for 5 hours, azeotropic removal of xylene along with water was performed, and the polyimide resin (PI-1) was obtained. When the GPC measurement of (PI-1) was performed, Mw=21000 in terms of polystyrene. In addition, the Tg of the polyimide resin (PI-1) was 55° C.

The obtained polyimide resin varnish was subjected to reprecipitation purification with pure water three times, then heat-drybg was performed at 60° C. for 3 days through the use of a vacuum oven, and thus the solid of the polyimide resin was obtained.

(PI-2)

In a 500 mL flask provided with a stirrer, a thermometer, and a nitrogen substitution device (nitrogen inflow tube), 140 g (0.07 mole) of polyoxypropylene diamine (trade name “D-2000” (molecular weight: about 2000) manufactured by BASF SE) and 3.72 g (0.015 mole) of BY16-871EG which are diamines, and 31.0 g (0.1 mole) of ODPA were added in small amounts to a solution in the flask. After finishing the addition, it was stirred at room temperature for 5 hours. Thereafter, the reflux condenser with the water receiver was attached to the flask and the temperature of the solution was raised to 180° C. while nitrogen gas was being blown therein, its temperature was maintained for five hours and the water was removed, with the result that the liquid polyimide resin (PI-2) was obtained. When GPC measurement of (PI-2) was performed, it had a weight average molecular weight (Mw) of 40000 in terms of polystyrene. In addition, the Tg of (PI-2) was 20° C. or less.

(PI-3)

In a 500 mL flask provided with a stirrer, a thermometer, and a nitrogen substitution device (nitrogen inflow tube), 100 g (0.05 mole) of polyoxypropylene diamine (trade name “D-2000” (molecular weight: about 2000) manufactured by BASF SE), 3.72 g (0.015 mole) of BY16-871EG and 7.18 g (0.02 mole) of 2,4-diamino-6-[2′-undecyl imidazoyl(1′)]ethyl-s-triazine (trade name “C11Z-A” manufactured by Shikoku Chemicals Corporation) which are diamines, and 31.0 g (0.1 mole) of ODPA were added in small amounts to a solution in a flask. After finishing the addition, it was stirred at room temperature for 5 hours. Thereafter, the reflux condenser with the water receiver was attached to the flask, the temperature of the solution was raised to 180° C. while nitrogen gas was being blown therein, the temperature was maintained for five hours and the water was removed, with the result that the liquid polyimide resin (PI-3) was obtained. When GPC measurement of the polyimide resin (PI-3) was performed, it had a weight average molecular weight (Mw) of 40000 in terms of polystyrene. In addition, the Tg of (PI-3) was 20° C. or less.

<Adhesive Composition>

Through the use of the polyimide resins (PI-1), (PI-2) and (PI-3) obtained as described above, respective constituents were blended at composition ratios (unit: part(s) by mass) listed in Tables 2 and 3 described below and the adhesive compositions (the varnish for forming an adhesive layer) of Examples 1-9 and Comparative Examples 1-5 were obtained.

In the Tables 2 and 3, each of symbols means the followings.

A-BPE4: manufactured by Shin Nakamura Chemical Co., Ltd., ethoxylated bisphenol A acrylate (5% weight loss temperature: 330° C., viscosity: 980 mPa·s)

M-140: manufactured by Toagosei Co., Ltd., 2-(1,2-cyclohexacarboxylmide)ethyl acrylate (5% weight loss temperature: 200° C., viscosity: 450 mPa·s)

AMP-20GY: manufactured by Shin Nakamura Chemical Co., Ltd., phenoxydiethylene glycol acrylate (5% weight loss temperature: 175° C., viscosity: 16 mPa·s)

YDF-8170C: manufactured by Tohto Kasei Co., Ltd., bisphenol F type bisglycidyl ether (5% weight loss temperature: 270° C., viscosity: 1300 mPa·s)

630LSD: manufactured by Japan Epoxy Resins Co., Ltd., glycidyl amine type epoxy resin (5% weight loss temperature: 240° C., viscosity: 600 mPa·s)

2PZCNS-PW: manufactured by Shikoku Chemicals Corporation, 1-cyanoethyl-2-phenylimidazoliumtrimellitate (5% weight reduction temperature: 220° C., average particle diameter: about 4 μm)

I-651: manufactured by Ciba Japan K.K., 2,2-dimethoxy-1,2-diphenylethane-1-one (5% weight reduction temperature: 170° C., i-ray absorption coefficient: 400 ml/gcm

Percumyl D: manufactured by NOF Corporation, dicumyl peroxide (one-minute half-life temperature: 175° C.)

NMP: manufactured by Kanto Chemical Co. Inc., N-methyl-2-pyrrolidone

TABLE 2

| | | Examples | | | | | | | | |
|---|---|---|---|---|---|---|---|---|---|---|
| | | 1 | 2 | 3 | 4 | 5 | 6 | 7 | 8 | 9 |
| Thermoplastic | PI-1 | 10 | — | 10 | — | — | — | — | — | — |
| resin | PI-2 | — | — | — | — | 5 | — | — | — | — |
| | PI-3 | — | — | — | — | — | 5 | — | — | — |
| (C) Epoxy | YDF-8170C | — | 20 | — | 20 | 20 | 20 | — | 10 | — |
| resin | 630LSD | 20 | — | 20 | — | — | — | 20 | — | — |
| (A) Compound | A-BPE4 | 40 | — | 80 | — | 40 | — | — | — | — |
| having a | M-140 | 40 | 80 | | 40 | 40 | 80 | 40 | 80 | 80 |
| carbon-carbon | AMP-20GY | — | — | — | 40 | — | — | 40 | — | — |
| double bond | | | | | | | | | | |
| within the | | | | | | | | | | |
| molecule | | | | | | | | | | |
| Curing | 2PZCNS- | 1 | 1 | 1 | 1 | 1 | — | 1 | 1 | 1 |
| accelerator | PW | | | | | | | | | |
| (B) | I-651 | 1 | 1 | 1 | 1 | 1 | 1 | 1 | 1 | 1 |
| Photoinitiator | | | | | | | | | | |
| Thermal radical | Percumyl D | 1 | 1 | 1 | — | 1 | 1 | 1 | 1 | 1 |
| generator | | | | | | | | | | |

TABLE 3

| | | Comparative Examples | | | | |
|---|---|---|---|---|---|---|
| | | 1 | 2 | 3 | 4 | 5 |
| Thermoplastic | PI-1 | 5 | — | 5 | — | — |
| resin | | | | | | |
| (C) Epoxy resin | YDF-8170C | 20 | 20 | 20 | 20 | 20 |
| (A) Compound | A-BPE4 | 40 | — | 160 | 80 | — |
| having a | M-140 | 40 | 80 | — | — | 40 |
| carbon-carbon | AMP-20GY | — | — | — | — | 40 |
| double bond | | | | | | |
| within the | | | | | | |
| molecule | | | | | | |
| Curing | 2PZCNS- | 1 | 1 | 1 | 1 | 1 |
| accelerator | PW | | | | | |
| (B) Photoinitiator | I-651 | 1 | 1 | 1 | 1 | — |
| Thermal radical | Percumyl D | 1 | 1 | 1 | 1 | 1 |
| generator | | | | | | |
| Coating solvent | NMP | 20 | 20 | — | — | — |

<Viscosity>

The viscosity was measured through the use of E-type viscometer (EHD-type rotational viscometer, standard cone) manufactured by Tokyo Keiki Inc. at a measurement temperature of 25° C. at a sample capacity of 4 cc at the number of revolutions set as shown in table 4 in accordance with the expected viscosity; values obtained 10 minutes after the start of the measurement were used as the measurement values. The results were shown in Tables 5 and 6.

TABLE 4

| Viscosity(mPa · s) | Number of revolutions (rpm) |
|---|---|
| 102400 - 10240 | 0.5 |
| 51200 - 5120 | 1.0 |
| 20480 - 2048 | 2.5 |
| 10240 - 1024 | 5.0 |
| 5120 - 512 | 10 |
| 2560 - 256 | 20 |
| 1024 - 102.4 | 50 |
| 512 - 51.2 | 100 |

<Film Thickness>

The adhesive composition was applied onto a silicon wafer by spin coating (2,000 rpm/10 s, 4,000 rpm/20 s) and a PET film subjected to mold-releasing treatment was laminated with a hand roller on the obtained coating film (adhesive layer), and exposure was performed at 1000 mJ/cm² by a high-precision parallel exposure machine (manufactured by ORC Manufacturing Co., Ltd., “EXM-1172-B-∞” (trade name)) with the result that the adhesive layer brought to the B-stage was formed. Thereafter, the PET film was peeled off, and the thickness of the adhesive layer was measured using the surface roughness measuring device (manufactured by Kosaka Laboratory). The results were shown in Tables 5 and 6.

<Maximum Melt Viscosity and Lowest Melt Viscosity>

The adhesive composition was applied onto the PET film such that its film thickness was 50 μm when brought to the B-stage and a PET film subjected to mold-releasing treatment was laminated with a hand roller on the obtained coating film, and exposure was performed at 1000 mJ/cm² by a high-precision parallel exposure machine (manufactured by ORC Manufacturing Co., Ltd., “EXM-1172-B-∞” (trade name)) with the result that the adhesive layer brought to the B-stage was formed. The formed adhesive layer was stuck to the Teflon (registered trade mark) sheet, and was pressurized by the roll (at a temperature of 60° C., a linear pressure of 4 kgf/cm, a transfer rate of 0.5 mlminute). After that, the PET film was peeled off, and another adhesive layer brought to the B-stage by exposure is laid on the adhesive layer, and by repeating the pressurizing and the stacking, an adhesive sample having a thickness of about 200 μm was obtained. The melt viscosity of the obtained adhesive sample was measured, through the use of the viscoelasticity measurement device (manufactured by Rheometric Scientific F.E. Ltd., the trade name: ARES) and a parallel plate having a diameter of 25 mm as a measurement plate, under the conditions of a temperature rise rate of 10° C./minute and a frequency of 1 Hz, and at measurement temperatures of 20 to 200° C. The maximum value of the melt viscosity at temperatures of 20 to 60° C. were read as the maximum melt viscosity, and the minimum value of the melt viscosity at temperatures of 80 to 200° C. were read as the lowest melt viscosity from the relationship between the obtained melt viscosity and the temperature. The results were shown in Tables 5 and 6.

<Surface Tack Force>

The adhesive composition was applied onto a silicon wafer by spin coating (2,000 rpm/10 s, 4,000 rpm/20 s). A PET film subjected to mold-releasing treatment was laminated on the obtained coating film (adhesive layer) and exposure was performed at 1000 mJ/cm² by a high-precision parallel exposure machine (manufactured by ORC Manufacturing Co., Ltd., “EXM-1172-B-∞” (trade name)) with the result that the adhesive layer brought to the B-stage was formed. After that, the surface tack force of the adhesive layer at 30° C. and 120° C. was measured through the use of a probe tacking tester manufactured by Rhesca Corporation under the conditions of probe diameter of 5.1 mm, peeling speed of 10 mm/s, contact load of 100 gf/cm², and contact time of 1 s. The results were shown in Tables 5 and 6.

<Shear Strength>

The adhesive composition was applied onto a silicon wafer by spin coating (2,000 rpm/10 s, 4,000 rpm/20 s). A PET film subjected to mold-releasing treatment was laminated on the obtained coating film and exposure was performed at 1000 mJ/cm² by a high-precision parallel exposure machine (manufactured by ORC Manufacturing Co., Ltd., “EXM-1172-B-∞” (trade name)) with the result that the adhesive layer brought to the B-stage was formed on the semiconductor wafer. After that, the PET film was peeled off, and thereafter, silicon chips of 3×3 mm square were cut from the silicon wafer. The cut silicon chips with the adhesive layer were placed on previously prepared silicon chips of 5×5 mm square and were compression bonded for two seconds at 120° C. while being pressurized at 100 gf. Then, they were heated in an oven at 120° C. for 1 hour and then at 180° C. for 3 hours, and samples in which the silicon chips have been made to adhere to each other were obtained. The shear adhesive strengths of the obtained samples were measured through the use of a shear strength tester “Dage-4000” (trade name) at room temperature and 260° C. The results were shown in Tables 5 and 6.

TABLE 5

| | | Examples | | | | | | | | |
|---|---|---|---|---|---|---|---|---|---|---|
| | | 1 | 2 | 3 | 4 | 5 | 6 | 7 | 8 | 9 |
| Viscosity (mPa · s) | | 800 | 550 | 1200 | 200 | 650 | 800 | 500 | 850 | 950 |
| Film thickness (μm) | | 7 | 5 | 10 | 2 | 6 | 7 | 5 | 7 | 9 |
| Maximum melt | 20-60° C. | 70000 | 50000 | 70000 | 30000 | 90000 | 50000 | 30000 | 50000 | 70000 |
| viscosity (Pa · s) | | | | | | | | | | |
| Lowest melt | 80-200° C. | 2000 | 200 | 4000 | 200 | 2000 | 200 | 200 | 400 | <100 |
| viscosity (Pa · s) | | | | | | | | | | |
| Surface tack force | 30° C. | 10 | 40 | 3 | 50 | 30 | 30 | 20 | 20 | 25 |
| (gf/cm²) | 120° C. | 250 | 400 | 200 | >500 | 400 | 400 | 350 | 350 | 250 |
| Shear strength | 25° C. | >10 | >10 | >10 | 8 | 7 | >10 | >10 | >10 | 2.5 |
| (MPa) | 260° C. | 1.4 | 1.0 | 1.2 | 0.30 | 0.20 | 0.35 | 0.70 | 0.70 | <0.10 |

TABLE 6

| | | Comparative Examples | | | | |
|---|---|---|---|---|---|---|
| | | 1 | 2 | 3 | 4 | 5 |
| Viscosity (mPa · s) | | 150 | 100 | 1000 | 1000 | 650 |
| Film thickness (μm) | | 2 | 2 | 10 | 9 | 5 |
| Maximum melt | 20-60° C. | <5000 | <5000 | >100000 | >100000 | <5000 |
| viscosity (Pa · s) | | | | | | |
| Lowest melt | 80-200° C. | * | * | >5000 | >5000 | <100 |
| viscosity (Pa · s) | | | | | | |
| Surface tack force | 30° C. | 380 | >500 | 1.2 | 1.5 | >500 |
| (gf/cm²) | 120° C. | >500 | >500 | 1.5 | 1.8 | >500 |
| Shear strength | 25° C. | peeled | peeled | 0.5 | peeled | peeled |
| (MPa) | 260° C. | peeled | peeled | <0.10 | peeled | peeled |

* Since the samples were obtained from adhesive varnishes containing solvent, they were affected by the volatilization of the solvent contained due to the temperature rise at the time of measurement, and thus it is impossible to estimate accurate measurement values.

### REFERENCE SIGNS LIST

1: semiconductor wafer, 2: semiconductor chip, 4: pressure sensitive adhesive tape (back grind tape), 5: adhesive composition (adhesive layer), 6: pressure sensitive adhesive tape (dicing tape), 7: supporting member, 8: grind device, 9: exposure device, 10: wafering, 11: dicing blade, 12: die bonding device, 14: heat board, 16: wire, 17: sealant, 30: solder ball, 100: semiconductor device, S1: circuit surface of semiconductor wafer, S2: rear face of semiconductor wafer

1. A method for manufacturing a semiconductor device, the method comprising the steps of:
forming an adhesive layer by forming an adhesive composition into a film on a surface opposite to a circuit surface of a semiconductor wafer;
bringing the adhesive layer to a B-stage by irradiation with light;
cutting the semiconductor wafer together with the adhesive layer brought to the B-stage into a plurality of semiconductor chips; and
making the semiconductor chip to adhere to a supporting member or another semiconductor chip by performing compression bonding, with the adhesive layer sandwiched therebetween.

2. The manufacturing method according to claim 1, wherein the adhesive composition is formed into the film in a state in which a back grind tape is provided on the circuit surface of the semiconductor wafer.

3. The manufacturing method according to claim 1, wherein a viscosity of the adhesive composition at 25° C. before being brought to the B-stage by irradiation with light is 10 to 30000 mPa·s.

4. The manufacturing method according to claim 1, wherein a film thickness of the adhesive layer brought to the B-stage by irradiation with light is 30 μm or less.

5. The manufacturing method according to claim 1, wherein a shear strength at 260° C. after adhesion of the semiconductor chip to the supporting member or another semiconductor chip is 0.2 MPa or more.

6. The manufacturing method according to claim 1,
wherein the film is formed by applying the adhesive composition to the surface opposite to the circuit surface of the semiconductor wafer by a spin coat method or a spray coat method.

7. The manufacturing method according to claim 1, wherein a 5% weight reduction temperature of the adhesive composition that has been brought to the B-stage by irradiation with light and then cured by heating is 260° C. or more.

8. The manufacturing method according to claim 1, wherein the adhesive composition contains (A) a compound having a carbon-carbon double bond and (B) a photoinitiator.

9. The manufacturing method according to claim 8, wherein (A) the compound having a carbon-carbon double bond includes a monofunctional (meth)acrylate compound.

10. The manufacturing method according to claim 9, wherein the monofunctional (meth)acrylate compound includes a compound having an imide group.

11. A semiconductor device obtainable by the manufacturing method according to claim 1.

12. A semiconductor wafer with an adhesive layer comprising:
a semiconductor wafer; and
an adhesive layer formed on a surface opposite to a circuit surface of the semiconductor wafer,
wherein the adhesive layer is brought to a B-stage by irradiation with light, and a maximum melt viscosity of the adhesive layer at a temperature of 20 to 60° C. is 5000 to 10000 Pa·s.

13. The semiconductor wafer with an adhesive layer according to claim 12, wherein a lowest melt viscosity of the adhesive layer at a temperature of 80 to 200° C. is 5000 Pa·s or less.

14. The semiconductor wafer with an adhesive layer according to claim 12, further comprising:
a dicing sheet,
wherein the dicing sheet is provided on a surface of the adhesive layer opposite to the semiconductor wafer.

15. The semiconductor wafer with an adhesive layer according to claim 14, wherein the dicing sheet has a base material film and a pressure sensitive adhesive layer provided on the base material film, and is provided in a direction in which the pressure sensitive adhesive layer is positioned on a side of the adhesive layer.

16. The semiconductor wafer with an adhesive layer according to claim 12, wherein the adhesive layer is formed with an adhesive composition in which a viscosity of the adhesive composition at 25° C. before being brought to the B-stage is 10 to 30000 mPa·s.

17. The semiconductor wafer with an adhesive layer according to claim 12, wherein the adhesive layer is a layer formed by bringing an adhesive composition containing (A) a compound having a carbon-carbon double bond and (B) a photoinitiator, to a B-stage.

18. The semiconductor wafer with an adhesive layer according to claim 17, wherein (A) the compound having a carbon-carbon double bond includes a monofunctional (meth)acrylate compound.

19. The semiconductor wafer with an adhesive layer according to claim 18, wherein the monofunctional (meth)acrylate compound includes a compound having an imide group.

20. A semiconductor device comprising: one or two or more semiconductor elements; and a supporting member,
wherein at least one of the semiconductor elements is a semiconductor element which is obtainable by cutting the semiconductor wafer with the adhesive layer according to claim 12 into pieces, and the semiconductor element is made, via the adhesive layer, to adhere to another semiconductor element or the supporting member.
